(19) United States
(12) Patent Application Publication
(10) Pub. No.: US 2026/0038603 A1
(43) Pub. Date: Feb. 5, 2026

(54) NON-VOLATILE MEMORY DEVICE OPERATING AT LOW VOLTAGE AND DATA SENSING METHOD THEREOF

(71) Applicant: SAMSUNG ELECTRONICS CO., LTD., Suwon-si (KR)

(72) Inventors: Sara Choi, Suwon-si (KR); Hyunkook Park, Suwon-si (KR); Ji-Sang Lee, Suwon-si (KR)

(21) Appl. No.: 19/226,751

(22) Filed: Jun. 3, 2025

(30) Foreign Application Priority Data
Jul. 31, 2024 (KR) 10-2024-0102132
Sep. 30, 2024 (KR) 10-2024-0133116

(51) Int. Cl. G11C 16/26; G11C 16/24; G11C 16/30

(52) U.S. Cl. CPC G11C 16/26; G11C 16/24; G11C 16/30

(57) ABSTRACT

Disclosed is a non-volatile memory device comprising, a cell array including memory cells connected to a bit line, a page buffer including a sensing node for sensing a memory cell selected through the bit line, and a control circuit configured to control a sensing operation of the page buffer, wherein the page buffer comprises, a separation transistor configured to separate the sensing node into a first sensing node and a second sensing node, and selectively transmit a voltage developed at the first sensing node to the second sensing node, and a sensing latch configured to latch data according to a voltage level of the second sensing node.

### CROSS-REFERENCE TO RELATED APPLICATIONS

This application claims priority under 35 U.S.C. § 119 to Korean Patent Application No. 10-2024-0102132 filed on Jul. 31, 2024, and Korean Patent Application No. 10-2024-0133116 filed on Sep. 30, 2024, in the Korean Intellectual Property Office, the entirety of each of which is incorporated herein by reference.

### BACKGROUND

Aspects of the present disclosure relate to semiconductor memory devices, for example, non-volatile memory devices including a page buffer operating at low voltage, and data sensing methods thereof.

Semiconductor memory devices can be broadly divided into volatile memory and non-volatile memory. Volatile memory (e.g. DRAM or SRAM) has fast read/write speeds, but stored data disappears when power is cut off. On the other hand, non-volatile memory such as NAND flash memory can maintain stored data even when power is cut off. Recently, vertical NAND flash memory devices that are stacked in three dimensions have become popular to improve integration.

Recently, the demand for low-power NAND flash memory has been rapidly increasing. In order to implement low-power NAND flash memory, the operating voltage of the memory device must be lowered. The lowering of the operating voltage of the memory device naturally requires a lowering of the operating voltage of the page buffer.

### SUMMARY

For purposes of this disclosure, it has been recognized that, in the circuit structure of a general page buffer, the minimum voltage of the sensing node is related to the level of the bit line, not the operating voltage. Therefore, the bit line voltage does not decrease as much as the operating voltage unless the cell current flowing through the bit line is reduced. As a result, as the operating voltage of the page buffer decreases, the voltage range formed at the sensing node also decreases relatively. In addition, as the area of the page buffer decreases, the variation of the trip voltage also increases. As a result, it becomes difficult to correctly determine whether the memory cell is on-cell/off-cell at a low operating voltage. In other words, when the operating voltage of the page buffer decreases, it is difficult to secure both the on-cell margin and the off-cell margin.

Some aspects of the present disclosure provide non-volatile memory devices capable of securing both on-cell margin and off-cell margin of a page buffer at a low operating voltage.

According to some implementations of the present disclosure, a non-volatile memory device includes: a cell array including memory cells connected to a bit line, a page buffer including a sensing node for sensing a memory cell selected through the bit line, and a control circuit configured to control a sensing operation of the page buffer, wherein the page buffer includes, a separation transistor configured to separate the sensing node into a first sensing node and a second sensing node, and selectively transmit a voltage developed at the first sensing node to the second sensing node, and a sensing latch configured to latch data according to a voltage level of the second sensing node.

According to some implementations of the present disclosure, a data sensing method of a non-volatile memory device includes: , prechacorging a first sensing node of a page buffer, developing the precharged first sensing node according to a program state of a selected memory cell, connecting the developed first sensing node to a second sensing node according to a sensing trip voltage defined by a gate voltage of a separation transistor, and latching data of the selected memory cell in a sensing latch according to a voltage formed at the second sensing node, wherein the separation transistor is connected between the first sensing node and the second sensing node, and the sensing trip voltage is higher than a latch trip voltage of the sensing latch.

According to some implementations of the present disclosure, a non-volatile memory device includes: a memory cell connected to a bit line, a page buffer configured to sense data stored in the memory cell through the bit line, and a control circuit configured to control a sensing operation of the page buffer, wherein the page buffer includes, a first sensing node connected to the bit line, a separation transistor having one end connected to the first sensing node and a gate provided with a sensing trip control voltage, a second sensing node connected to the other end of the separation transistor, and a sensing latch configured to latch data according to a voltage level of the second sensing node, wherein, a trip voltage of the sensing latch is lower than a trip voltage of the separation transistor defined by the sensing trip control voltage.

### BRIEF DESCRIPTION OF THE FIGURES

The above and other objects and features of the present disclosure will become apparent by describing in detail examples thereof with reference to the accompanying drawings.

FIG. 1 is a diagram showing a reduction in sensing margin of a page buffer due to a lower voltage of a flash memory device.

FIG. 2 is a block diagram showing an example of a non-volatile memory device.

FIG. 3 is a circuit diagram showing an example of a structure of a memory block in the cell array of FIG. 2.

FIG. 4 is a block diagram showing an example of a configuration of a cell array and a page buffer circuit.

FIG. 5 is a circuit diagram showing example of a structure of a page buffer having a separated sensing node.

FIG. 6 is a diagram showing an example of operating characteristics of the page buffer of FIG. 5.

FIG. 7 is a diagram showing an example of operation of a page buffer for sensing a memory cell in an off-cell state.

FIG. 8 is a diagram showing an example of operation of a page buffer for sensing a memory cell in an on-cell state.

FIG. 9 is a timing diagram showing an example of control method of a sensing node during a data sensing operation.

FIG. 10 is a diagram illustrating an example of a technique for applying a single precharge double sensing technique in a data sensing operation.

FIG. 11 is a timing diagram showing an example of a data sensing method.

FIG. 12 is a timing diagram showing an example of a data sensing method.

FIG. 13 is a circuit diagram showing an example of a structure of a page buffer having a separated sensing node.

FIG. 14 is a timing diagram showing an example of a data sensing method.

FIG. 15 is a timing diagram showing an example of a data sensing method.

FIG. 16 is a block diagram showing an example of a configuration of a cell array and a page buffer circuit.

FIG. 17 is a diagram showing an example of operating characteristics of a page buffer.

FIG. 18 is a circuit diagram showing an example of a structure of a page buffer having a separated sensing node.

FIG. 19 is a timing diagram showing an example of a method of controlling a sensing node during a data sensing operation.

FIG. 20 is a circuit diagram showing an example of a structure of a page buffer having a separated sensing node.

FIG. 21 is a timing diagram showing an example of a data sensing method.

### DETAILED DESCRIPTION

The same reference numbers used in the description and drawings refer to the same or like parts.

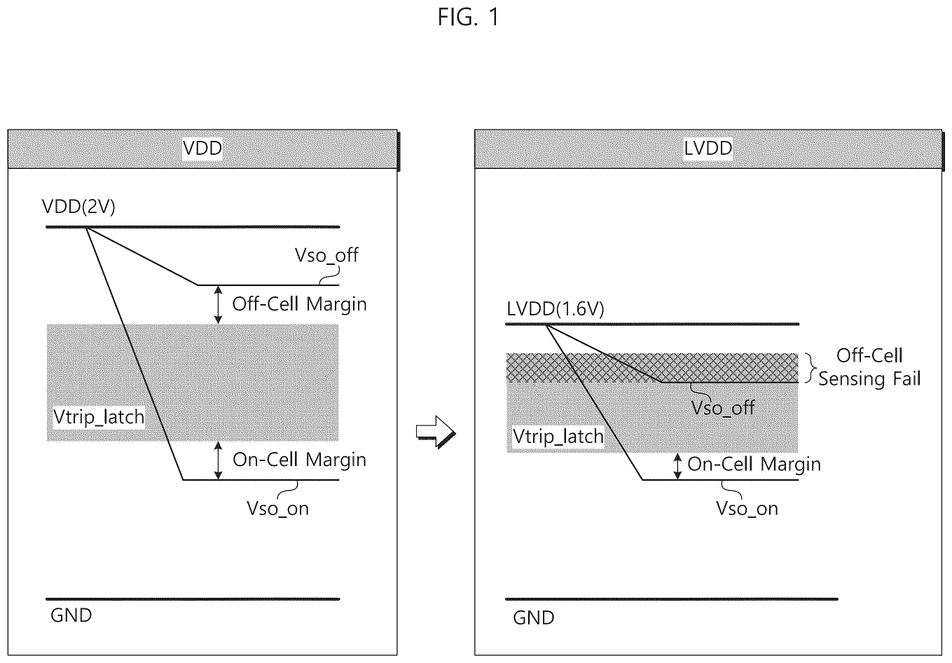

FIG. 1 is a diagram showing the reduction in sensing margin of a page buffer due to the lowering of the voltage of a flash memory device. Referring to FIG. 1, as the operating voltage of the page buffer decreases, it becomes difficult to correctly determine whether the sensed memory cell is on-cell or off-cell.

In the case of a page buffer of a general flash memory, the level of a sensing node (hereinafter, SO) is developed according to the cell current flowing through the bit line. The sensing node SO is directly connected to the sensing latch. Therefore, the trip voltage of the page buffer, which distinguishes whether the sensed memory cell is on-cell or off-cell, is the same as the trip voltage of the sensing latch. In addition, since the sensing latch mainly uses a static latch, the trip voltage fluctuation of the sensing latch is also very large.

In order to implement a low-power flash memory, a low voltage of the operating voltage VDD is required. The operating voltage of the page buffer may also be lowered due to the low voltage. At a typical operating voltage (VDD=2V), the on-cell margin and off-cell margin can be sufficiently secured to compensate for the trip voltage fluctuation of the sensing latch. However, it is difficult to secure the off-cell margin in a low operating voltage (e.g., LVDD=1.6V) environment. This is because the minimum voltage of the sensing node SO is related to the cell current flowing in the bit line BL. In other words, the bit line voltage does not decrease as much as the operating voltage decreases without reducing the cell current flowing through the bit line. Therefore, the voltage range formed at the sensing node SO of the page buffer in a low operating voltage (e.g., LVDD=1.6V) environment is greatly reduced. In addition, as the area of the page buffer decreases, the fluctuation of the trip voltage also increases. For this reason, it is difficult to sufficiently secure the on-cell margin or the off-cell margin in a low operating voltage LVDD environment.

Some aspects of the present disclosure provide a technology that can secure both on-cell margin and off-cell margin by applying a technique of separating a sensing node SO of a page buffer in a low operating voltage LVDD environment.

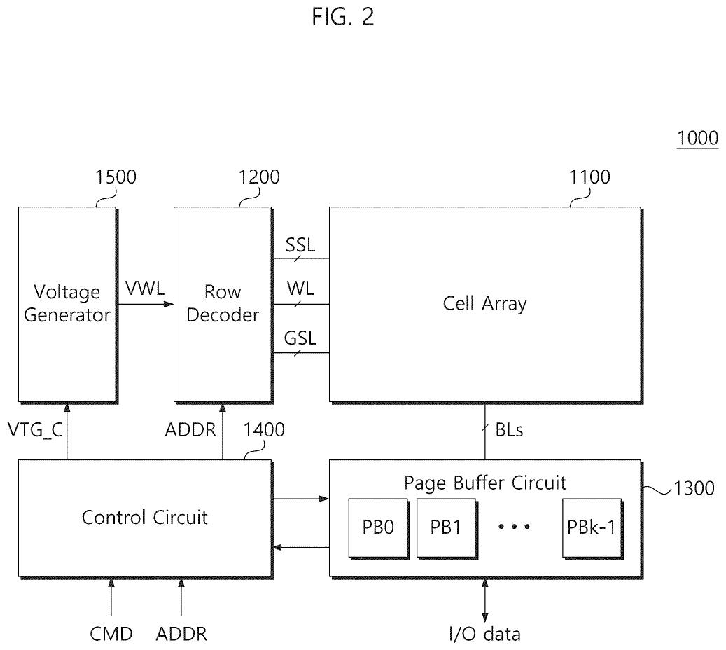

FIG. 2 is a block diagram showing a non-volatile memory device. Referring to FIG. 2, a non-volatile memory device 1000 may include a cell array 1100, a row decoder 1200, a page buffer circuit 1300, a control circuit 1400, and a voltage generator 1500.

The cell array 1100 is connected to the row decoder 1200 through word lines WLs or select lines SSL and GSL. The cell array 1100 is connected to the page buffer circuit 1300 through bit lines BLs. The cell array 1100 may include a plurality of NAND cell strings. Each channel of the NAND cell strings may be formed in a vertical direction on the substrate. The cell array 1100 includes a plurality of memory cells forming a NAND cell string. The plurality of memory cells may be programmed, erased, and sensed by voltages provided to bit lines BLs or word lines WLs. The program operation may be performed in units of pages, and the erase operation may be performed in units of blocks.

The cell array 1100 may be provided as a three-dimensional memory array. The three-dimensional memory array may be monolithically formed on one or more physical levels of arrays of memory cells having an active area arranged on a silicon substrate and circuitry associated with the operation of the memory cells. The circuitry associated with the operation of the memory cells may be located within or on the substrate.

The row decoder 1200 may select one of the memory blocks of the cell array 1100 in response to an address ADDR. The row decoder 1200 can select one of the word lines of the selected memory block in response to the address ADDR. The row decoder 1200 transmits a voltage VWL corresponding to the operation mode to the word line of the selected memory block. During a program operation, the row decoder 1200 transmits a program voltage and a verification voltage to the selected word line, and a pass voltage to the non-selected word line. During a read operation, the row decoder 1200 transmits a read voltage to the selected word line, and a read pass voltage to the non-selected word line.

The page buffer circuit 1300 operates as a write driver or a sense amplifier. During a program operation, the page buffer circuit 1300 transmits a bit line voltage corresponding to data to be programmed to the bit lines BLs of the cell array 1100. During a data read operation or a verification read operation, the page buffer circuit 1300 detects data stored in the selected memory cell through the bit lines BLs. Here, the data read operation means a general read operation that senses data stored in the cell array 1100 according to an external request. And the operation that senses whether data is normally written to the selected memory cell during the program operation is called a verify read operation. The page buffer circuit 1300 detects the cell current flowing through the bit line BL in the data read operation and the verify read operation and latches the data stored in the memory cell. The data is latched by detecting the level change of the sensing node SO according to the cell current flowing through the bit line BLs.

Recently, as the demand for low power has rapidly increased, the demand for non-volatile memory devices driven by low operating voltage is increasing. As the low operating voltage LVDD is applied, the operating voltage (VDD, for example, 2V) of the page buffer circuit 1300 is also lowered to the low operating voltage (LVDD, for example, 1.6V) level. However, due to the structure that senses the cell current flowing through the bit line, the minimum voltage of the sensing node SO of the page buffer circuit 1300 is related to the voltage of the bit line, not the operating voltage. As a result, unless the cell current flowing through the bit line is reduced, the voltage level of the bit line does not decrease as much as the operating voltage.

As the operating voltage of the page buffer circuit 1300 decreases, the voltage range formed according to the charging and discharging of the sensing node SO also decreases relatively. In addition, as the area of the page buffer circuit 1300 decreases, the variation of the trip voltage also tends to increase. Therefore, at a low operating voltage LVDD, it may be difficult for the page buffer circuit 1300 to correctly determine whether the memory cell is on-cell or off-cell. As a result, when the operating voltage VDD of the page buffer circuit 1300 decreases, it may become difficult to secure both the on-cell margin and the off-cell margin.

The page buffer circuit 1300 according to some implementations of the present disclosure includes a plurality of page buffers PB0 to PBk-1 each having a sensing node SO separated into a first sensing node SO1 responsible for sensing and a second sensing node SO2 for a data latch. For example, the sensing node SO of each of the plurality of page buffers PB0 to PBk-1 is separated into two parts by a separation transistor implemented as a PMOS transistor. The first sensing node SO1 is precharged and developed according to a cell current sensed through a bit line. Then, the developed charge of the first sensing node SO1 is selectively transferred to the second sensing node SO2 via the separation transistor. The transfer of the precharged charge from the first sensing node SO1 to the second sensing node SO2 is determined according to the gate voltage of the separation transistor. And the voltage level of the second sensing node SO2 is latched as data by the sensing latch.

As a result, the page buffer circuit 1300 can separate the sensing trip voltage Vtrip_sensing that detects whether it is on-cell/off-cell and the latch trip voltage Vtrip_latch of the sensing latch through the separation of the sensing node SO. Therefore, both the on-cell margin and the off-cell margin can be secured even in the low operating voltage LVDD environment. A detailed description of the plurality of page buffers PB0 to PBk-1 will be provided below.

The control circuit 1400 controls the page buffer circuit 1300, the row decoder 1200, and the voltage generator 1500 in response to a command CMD transmitted from the outside. The control circuit 1400 can control the voltage generator 1500, the page buffer circuit 1300, and the row decoder 1200 to perform program, read, and erase operations on the selected memory cell according to the command CMD. The control circuit 1400 can transmit an address ADDR to the row decoder 1200 and provide a voltage control signal VTG_C to the voltage generator 1500. For example, the control circuit 1400 can provide control signals for controlling the separated sensing nodes SO1 and SO2 of each of the plurality of page buffers PB0 to PBk-1.

The voltage generator 1500 generates various types of word line voltage VWL to be supplied to each word line and a voltage to be supplied to the bulk (e.g., the well region) where the memory cells are formed according to the control of the control circuit 1400. The word line voltages to be supplied to each word line may include a program voltage, a pass voltage, a select read voltage, and a non-select read voltage.

Although not shown, the non-volatile memory device 1000 may further include components such as an input/output buffer or a mass bit counter. As described above, the non-volatile memory device 1000 can provide on-cell margin and off-cell margin even at a low operating voltage LVDD through a separated sensing node SO structure.

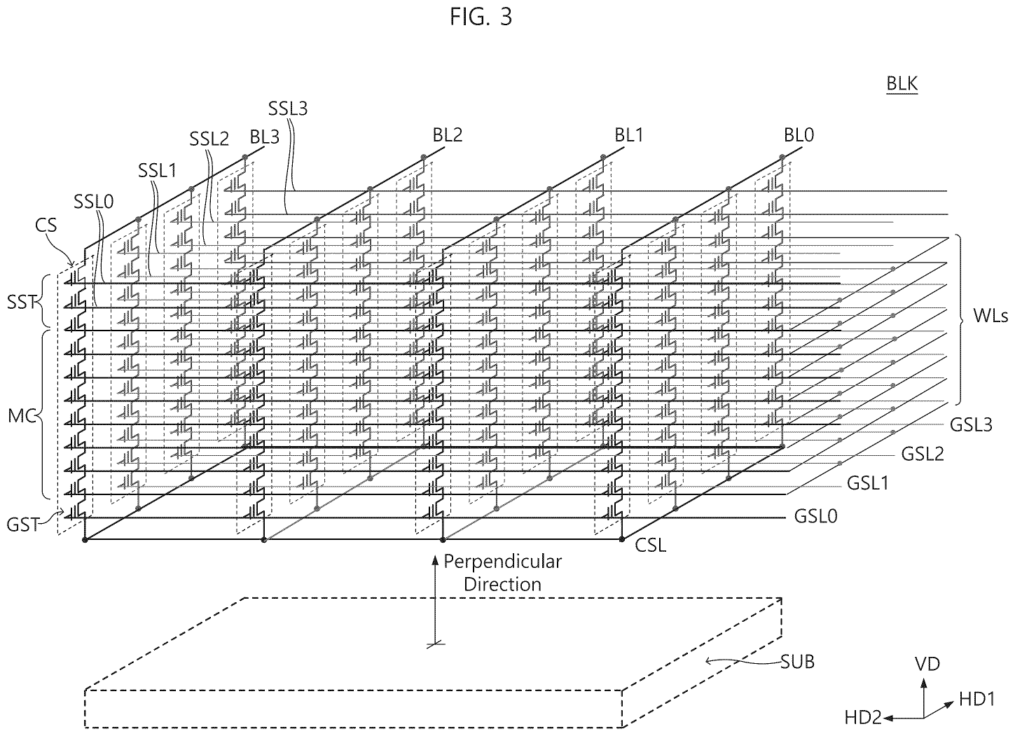

FIG. 3 is a circuit diagram showing an example of a structure of a memory block constituting the cell array of FIG. 2. Referring to FIG. 3, cell strings CS are formed between bit lines (BL0, BL1, BL2 and BL3) and a common source line CSL to form a memory block BLK.

A plurality of cell strings are formed between the bit line BL0 and the common source line CSL. The string selection transistor SST of the cell strings CS are connected to the corresponding bit line BL. The ground selection transistor GST of the cell strings CS are connected to the common source line CSL. Memory cells MCs are provided between the string selection transistor SST and the ground selection transistor GST of the cell string CS.

Each of the cell strings CS includes a ground selection transistor GST. The ground selection transistors included in the cell strings CS can be controlled by the ground selection line GSL. Or, the cell strings corresponding to each row can be controlled by different ground selection lines.

In the above, the circuit structure of the memory cells included in one memory block BLK has been briefly described. However, the circuit structure of the illustrated memory block is a simplified structure for convenience of explanation, and the actual memory block is not limited to the illustrated example. That is, it will be well understood that one physical block can include more semiconductor layers, bit lines BLs, and string selection lines SSLs.

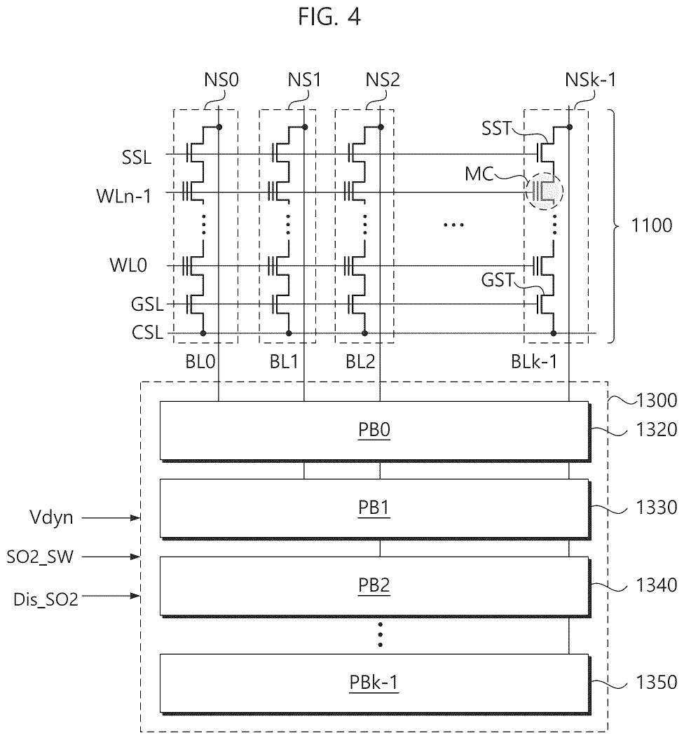

FIG. 4 is a block diagram showing a configuration of a cell array and a page buffer circuit. Referring to FIG. 4, each of the plurality of page buffers PB0 to PBk-1 included in the page buffer circuit 1300 performs data sensing and latching of a separated sensing node SO in response to sensing node control signals (Vdyn, SO2_SW, Dis_SO2).

Each of the plurality of NAND cell strings NS0 to NSk-1 may include a ground selection transistor GST connected to a ground selection line GSL. Each of the NAND cell strings NS0 to NSk-1 may include a plurality of memory cells MC connected to a plurality of word lines WL0 to WLn-1, respectively, and a string selection transistor SST connected to a string selection line SSL. And the ground selection transistor GST, the memory cell MC, and the string selection transistor SST may be connected in series with each other.

The page buffer circuit 1300 may include a plurality of page buffers PB0 to PBk-1. The first page buffer PB0 may be connected to the first NAND cell string NS0 via the first bit line BL0, and the k-th page buffer PBk-1 may be connected to the k-th NAND cell string NSk-1 via the k-th bit line BLk-1. Here, ‘k’ is a positive integer. For example, ‘k’ may be 8, and the page buffer circuit 1300 may have a structure in which eight stages of page buffers PB0 to PB7 are arranged in a row.

Each of the plurality of page buffers PB0 to PBk-1 may program or sense data to selected memory cells. In particular, each of the plurality of page buffers PB0 to PBk-1 has a separated sensing node which can sufficiently provide on-cell margin and off-cell margin even under low operating voltage LVDD conditions. By the separated sensing node, each of the plurality of page buffers PB0 to PBk-1 can separate the trip voltage Vtrip_sensing of the sensing node SO from the trip voltage Vtrip_latch of the sensing latch. That is, even if it is difficult to lower the voltage of the sensing node SO under low operating voltage LVDD conditions, the trip voltage Vtrip_latch of the sensing latch can be lowered by using the separated sensing node. To this end, each of the plurality of page buffers PB0 to PBk-1 can perform data sensing and latching of a separated sensing node SO in response to a sensing node control signals (Vdyn, SO2_SW, Dis_SO2). In addition, it is possible to adjust the trip voltage Vtrip_latch of the sensing latch to improve cell distribution according to temperature change. For example, a method of varying the gate voltage Vdyn of the separated transistor according to temperature can be used.

The page buffer circuit 1300 can provide both on-cell margin and off-cell margin of the memory cell through the separated sensing node SO structure even in a low operating voltage LVDD environment. Therefore, the non-volatile memory device 1000 can provide high data reliability while satisfying low voltage requirements.

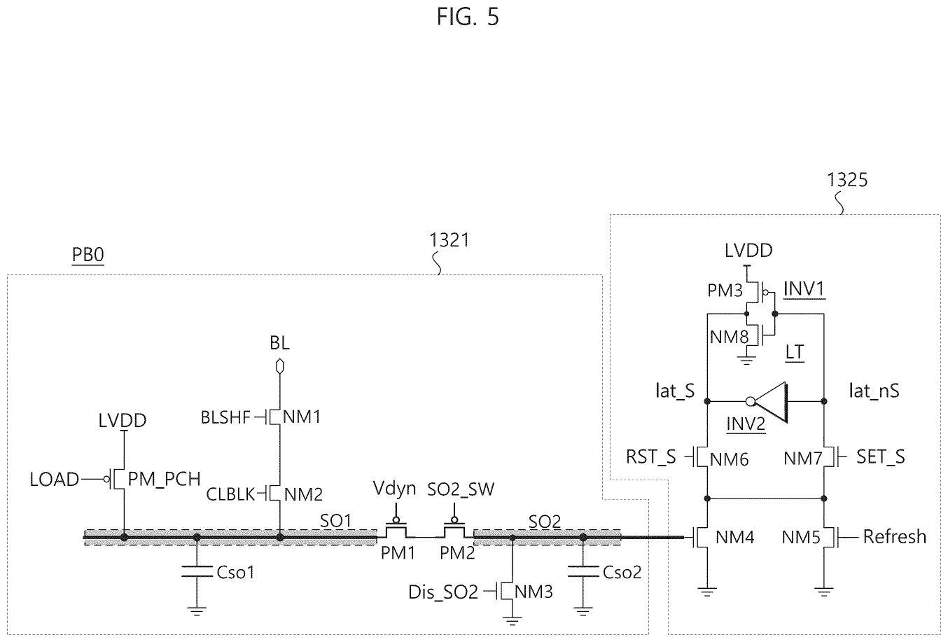

FIG. 5 is a circuit diagram showing an example of a structure of a page buffer having a separated sensing node. Referring to FIG. 5, a page buffer PB0, which is one of a plurality of page buffers PB0 to PBk-1, may include a sensing unit 1321 and a sensing latch 1325. The sensing node of the sensing unit 1321 is separated into a first sensing node SO1 and a second sensing node SO2 by a separation transistor PM1.

The sensing unit 1321 may include NMOS transistors NM1 and NM2 for connecting the first sensing node SO1 to a bit line BL. Each of the NMOS transistors NM1 and NM2 is switched by control signals BLSHF and CLBLK. The NMOS transistor NMI can be driven by a bit line shut-off signal BLSHF, and the NMOS transistor NM2 can be driven by a bit line connection control signal CLBLK. In addition, the sensing unit 1321 can further include a precharge transistor PM_PCH formed by a PMOS transistor. The precharge transistor PM_PCH is connected to the first sensing node SO1 and can precharge the first sensing node SO1 by a load signal LOAD.

The sensing unit 1321 includes the separation transistor PM1 for driving the sensing node by separating it into the first sensing node SO1 and the second sensing node SO2. The separation transistor PM1 can be formed, for example, by a PMOS transistor. The gate of the separation transistor PM1 is provided with a sensing trip control voltage Vdyn provided from the control circuit 1400. During the sensing operation, if the voltage level precharged to the first sensing node SO1 is higher than the sum of the sensing trip control voltage Vdyn and the threshold voltage Vth_dyn of the separation transistor PM1, the separation transistor PM1 is turned on. According to the turn-on of the separation transistor PM1, the charge precharged to the first sensing node SO1 can be shared to the second sensing node SO2.

The switch transistor PM2 can be connected in series between the separation transistor PM1 and the second sensing node SO2. When the separation transistor PM1 is turned on and the charge precharged from the first sensing node SO1 moves to the second sensing node SO2, the amount of charge moved can be controlled according to the pulse width at which the switch transistor PM2 is turned on. The switch transistor PM2 is turned on or off by the switch control signal SO2_SW. Here, the positions of the separation transistor PM1 and the switch transistor PM2 can be exchanged with each other. In addition, a discharge transistor NM3 can be added for initializing the second sensing node SO2. A discharge control signal Dis_SO2 for grounding the second sensing node SO2 is provided to the gate of the discharge transistor NM3.

The sensing latch 1325 latches data according to the voltage level of the second sensing node SO2. To this end, the sensing latch 1325 may include an NMOS transistor NM4 of which the gate is connected to the second sensing node SO2, a refresh transistor NM5, a reset transistor NM6, a set transistor NM7, and first and second inverters INV1 and INV2. The first and second inverters INV1 and INV2 may each be composed of a PMOS transistor and an NMOS transistor. For example, the first inverter INV1 includes a PMOS transistor PM3 that operates as a pull-up transistor and an NMOS transistor NM8 that operates as a pull-down transistor. The second inverter INV2 also has the same configuration as the first inverter INV1. An input terminal of the first inverter INV1 and an output terminal of the second inverter INV2 may be connected to an inversion latch node Lat_nS. The output terminal of the first inverter INV1 and the input terminal of the second inverter INV2 can be connected to the latch node Lat_S.

The NMOS transistor NM4 provided for grounding the latch LT is turned on or off according to the voltage level of the second sensing node SO2. The latch LT is tripped at the time when the reset signal RST_S or the set signal SET_S transitions to a high level. That is, the latch LT will be tripped or maintained in the current state depending on the level of the second sensing node SO2. For example, the trip voltage for the level of the second sensing node SO2 of the sensing latch 1325 is determined by the PMOS transistor PM3 and the NMOS transistor NM4 of the first inverter INV1. That is, at the moment of trip, the PMOS transistor PM3 of the first inverter INV1 can operate as a pull-up transistor, and the NMOS transistor NM4 can operate as a pull-down transistor. By these operating conditions, the latch trip voltage Vtrip_latch of the sensing latch 1325 can be set under the low operating voltage LVDD condition by setting the threshold voltage of the pull-up transistor and the NMOS transistor NM4 of the inverters INV1 and INV2.

Here, the latch LT composed of the inverters INV1 and INV2 can also be composed of a tri-state latch (Tri-state LT: hereinafter, TLT). The tri-state latch TLT includes PMOS transistors (not shown) for switching the low operating voltage LVDD to block the PMOS transistor (e.g., PM3) of the inverters INV1 and INV2 in the high section of the reset signal RST_S where the latch of the trip level occurs. Therefore, the trip level of the tri-state latch TLT is entirely or substantially dependent on the operation of the NMOS transistors (e.g., NM8) of the inverters INV1 and INV2 in the latch section of the sensing node without any racing.

In the above, an example of a structure of a page buffer PB0 having a separated sensing node has been described. By separating the sensing node, it is possible to secure the on-cell margin and the off-cell margin even at the low operating voltage LVDD condition.

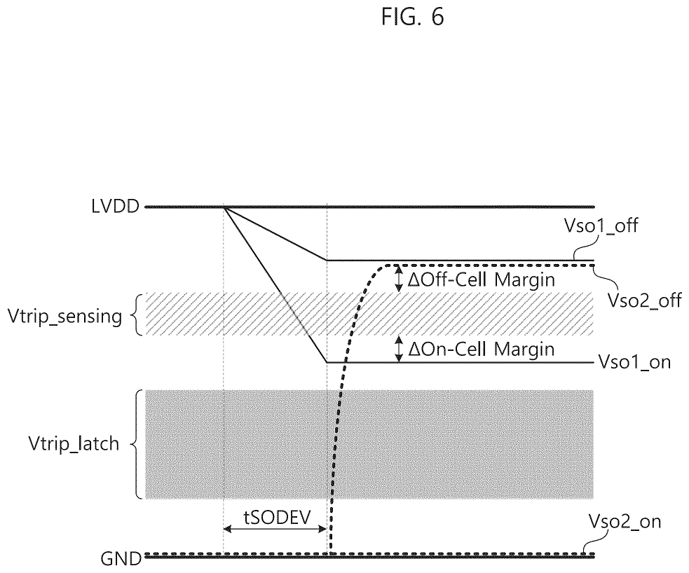

FIG. 6 is a diagram showing the operating characteristics of the page buffer of FIG. 5. Referring to FIG. 6, the page buffer PB0 can separate the sensing trip voltage Vtrip_sensing and the latch trip voltage Vtrip_latch through the separation of the sensing node SO under the low operating voltage LVDD condition.

Assuming that the level of the precharged first sensing node SO1 corresponds to the low operating voltage LVDD, the charge of the precharged first sensing node SO1 is developed according to the cell current of the bit line BL during the sensing node development period tSODEV. In the case of an on-cell, the voltage of the first sensing node SO1 is developed as shown in the voltage curve Vso1_on. On the other hand, in the case of an off-cell, the voltage of the first sensing node SO1 is developed as shown in the voltage curve Vso1_off.

When the sensed memory cell corresponds to an on-cell, the level of the first sensing node SO1 becomes lower than the sensing trip voltage Vtrip_sensing set by the gate voltage of the separation transistor PM1. Therefore, the separation transistor PM1 remains in a turn-off state, and the first sensing node SO1 and the second sensing node SO2 remain electrically separated. Therefore, the level of the second sensing node SO2 becomes a ground GND state. That is, in the case of an on-cell, the voltage of the second sensing node SO2 corresponds to the voltage curve Vso2_on.

On the other hand, when the sensed memory cell corresponds to an off-cell, the level of the first sensing node SO1 becomes higher than the sensing trip voltage Vtrip_sensing set by the gate voltage of the separation transistor PM1. Accordingly, the separation transistor PM1 is turned on, and the first sensing node SO1 and the second sensing node SO2 are electrically connected. And according to the distribution of the charge developed in the first sensing node SO1, the voltage of the second sensing node SO2 rises as shown in the voltage curve Vso2_off.

The size of the sensing trip voltage Vtrip_sensing can be controlled by the sensing trip control voltage Vdyn provided to the gate of the separation transistor PM1. And the latch trip voltage Vtrip_latch can be adjusted by setting the threshold voltage of the pull-up transistor of the inverters INV1 and INV2 of the sensing latch (1325, see FIG. 5) and the NMOS transistor NM4. In the case of on-cell, since the voltages of the first sensing node SO1 and the second sensing node SO2 are almost the same, the latch trip voltage Vtrip_latch can be set lower than the sum of the sensing trip control voltage Vdyn and the threshold voltage of the separation transistor PM1.

In addition, in the case of the inverters INV1 and INV2 implemented in the form of a static latch, the variation of the trip voltage was relatively large because it was a P/N fighting structure. In some implementations of the page buffers described herein, the variation of the trip voltage depends on the threshold voltage variation of the separation transistor PM1 implemented as the PMOS transistor. Therefore, the voltage variation range of the sensing trip voltage Vtrip_sensing can be drastically reduced. Due to these characteristics, sufficient on-cell margin and off-cell margin can be secured in the page buffer PB0 under low operating voltage LVDD conditions.

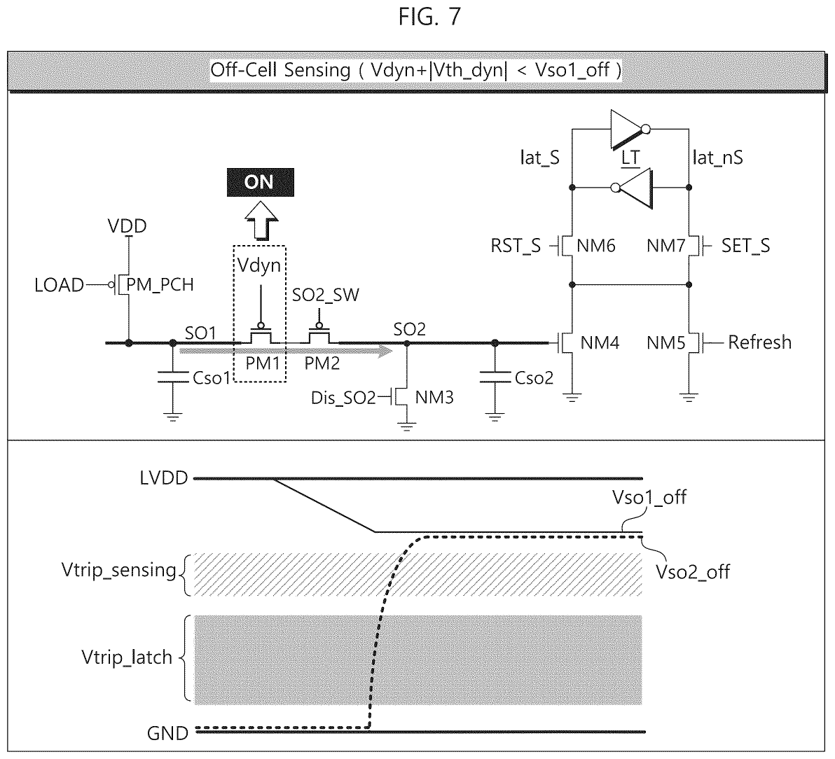

FIG. 7 is a diagram showing the operation of the page buffer that senses a memory cell in an off-cell state. Referring to FIG. 7, the cell current of the bit line is blocked by the off-cell, and the voltage formed at the first sensing node SO1 turns on the separation transistor PM1. Therefore, the voltages of the first sensing node SO1 and the second sensing node SO2 are formed at almost the same level.

When sensing the off-cell, the charge precharged at the first sensing node SO1 will be developed to a level higher than the sensing trip voltage Vtrip_sensing. That is, the voltage of the first sensing node SO1 changes in the form of a voltage curve Vso1_off due to the development action. In this case, the voltage Vso1_off of the first sensing node SO1 becomes higher than the sum of the sensing trip control voltage Vdyn and the threshold voltage Vth_dyn provided to the gate of the separation transistor PM1. Therefore, the separation transistor PM1 is turned on.

According to the turn-on of the separation transistor PM1, the first sensing node SO1 and the second sensing node SO2 are electrically connected. And the charge precharged to the first sensing node SO1 moves by the charge sharing of the first sensing node capacitance Csol and the second sensing node capacitance Cso2. Therefore, the voltage Vso2_off of the second sensing node SO2 rises to almost the same level as the voltage Vso1_off of the first sensing node SO1.

As a result, even under low operating voltage LVDD condition, the voltage developed at the second sensing node SO2 during sensing of an off-cell can be higher than the sensing trip voltage Vtrip_sensing. That is, the voltage Vso2_off at the off-cell sensing of the second sensing node SO2 where the data latch occurs through the separation of the sensing node SO can be amplified to be higher than the sensing trip voltage Vtrip_sensing. That is, in the page buffer PB0, sufficient off-cell margin can be secured under low operating voltage LVDD condition.

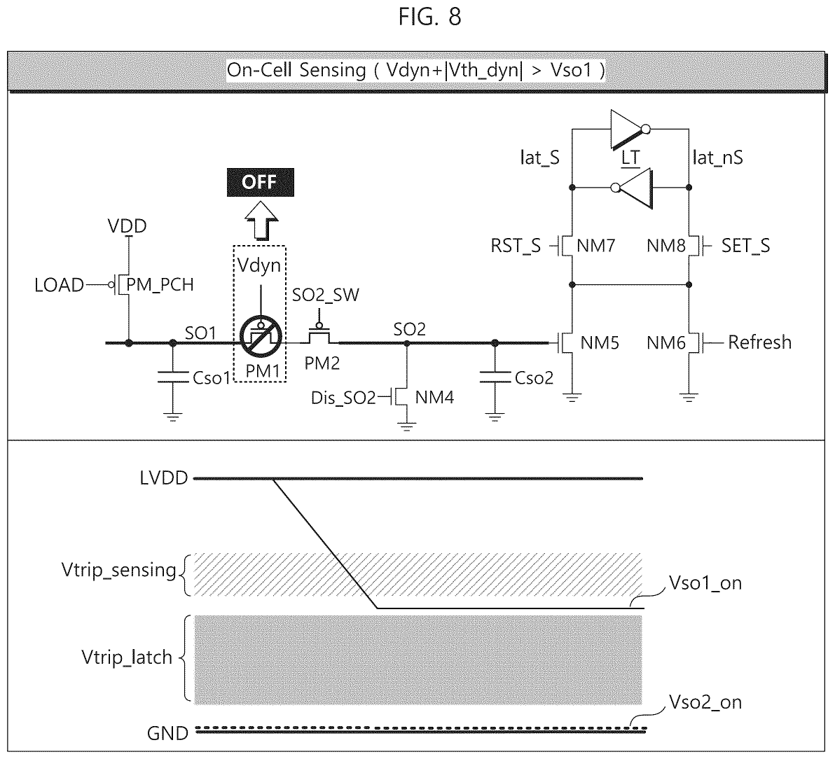

FIG. 8 is a diagram showing the operation of the page buffer to sense a memory cell in an on-cell state. Referring to FIG. 8, the cell current of the bit line flows by sensing of an on-cell, and the voltage Vso1_on of the first sensing node SO1 drops by the discharge of the precharged charge. Therefore, the separation transistor PM1 is maintained in a turn-off state by the voltage Vso1_on of the lowered first sensing node SO1. Therefore, the first sensing node SO1 and the second sensing node SO2 are electrically disconnected.

When sensing the on-cell, the charge precharged in the first sensing node SO1 will be developed to a level lower than the sensing trip voltage Vtrip_sensing. That is, the voltage of the first sensing node SO1 changes in a shape like the voltage curve Vso1_on by the development action. In this case, the voltage Vso1_on of the first sensing node SO1 becomes lower than the sum of the sensing trip control voltage Vdyn and the threshold voltage Vth_dyn provided to the gate of the separation transistor PM1. Therefore, the separation transistor PM1 will be maintained in a turn-off state.

According to the turn-off state of the separation transistor PM1, the first sensing node SO1 and the second sensing node SO2 are electrically disconnected. And the sharing of the charge precharged in the first sensing node SO1 to the second sensing node SO2 is also blocked. Therefore, the voltage Vso2_on of the second sensing node SO2 is maintained at the ground GND level.

As a result, the voltage of the second sensing node SO2 is maintained at the ground GND level by the disconnection of the separation transistor PM1 when sensing the on-cell under the low operating voltage LVDD condition. That is, in the page buffer PB0, sufficient on-cell margin can be secured under the low operating voltage LVDD condition.

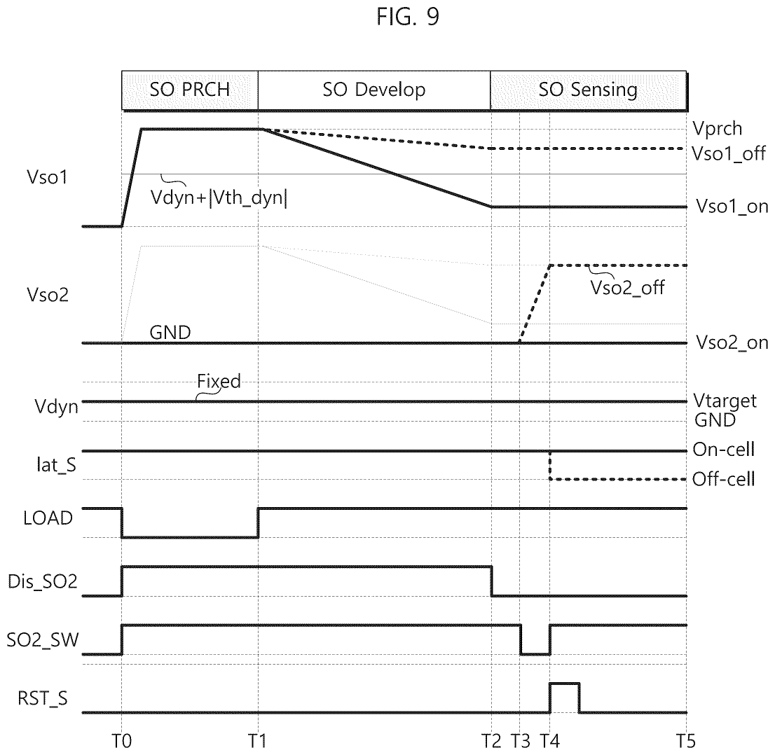

FIG. 9 is a timing diagram showing a control method of a sensing node when a data sensing operation is performed in the page buffer of FIG. 5. Referring to FIG. 5 and FIG. 9, whether a memory cell is on-cell or off-cell is detected with a high sensing margin even in a low operating voltage LVDD condition by using a separated first sensing node SO1 and a second sensing node SO2. Here, the sensing trip control voltage Vdyn applied to the gate of the separation transistor PM1 may be maintained at a fixed level.

At time T0, the precharge operation of the first sensing node SO1 starts. The load signal LOAD is activated to a low level (or, 0V) for the precharge of the first sensing node SO1. Then, the precharge transistor PM_PCH is turned on, and the first sensing node SO1 will rise to the precharge voltage Vprch level. At this time, the discharge control signal Dis_SO2 transitions to a high level to initialize the second sensing node SO2. And the switch control signal SO2_SW is deactivated to a high level. Then, regardless of the operation of the separation transistor PM1, the first sensing node SO1 and the second sensing node SO2 are electrically disconnected.

At time T1, the development of the first sensing node SO1 is performed. For the development of the first sensing node SO1, the control signal BLSHF connecting the bit line BL and the first sensing node SO1 transitions to a high level. And the load signal LOAD is deactivated to a high level. When the load signal LOAD is deactivated, the precharge transistor PM_PCH is turned off. Then, the first sensing node SO1 precharged with the precharge voltage Vprch is developed according to the level of the bit line BL. At this time, the discharge control signal Dis_SO2 maintains a high level. Then, when the switch control signal SO2_SW is deactivated to the high level, the switch transistor PM2 electrically disconnects the first sensing node SO1 and the second sensing node SO2. By the developing action, the voltage of the first sensing node SO1 precharged with the precharge voltage Vprch level changes to the first off-cell voltage Vso1_off when an off-cell is sensed. On the other hand, when sensing an on-cell, the voltage of the first sensing node SO1 precharged to the precharge voltage Vprch level will be lowered to the first on-cell voltage Vso1_on.

At time T2, the latch operation of the sensing latch 1325 for the second sensing node SO2 begins. To this end, the discharge control signal Dis_SO2 is deactivated to a low level at time T2. Then, the discharge transistor NM3 is turned off, and the initialization of the second sensing node SO2 is terminated. Then, the switch control signal SO2_SW transitions to a low level from time T3 to time T4. Then, the switch transistor PM2 is turned on during the pulse period from time T3 to time T4, and the precharged charge of the first sensing node SO1 moves to the second sensing node SO2. When sensing the off-cell, the level of the voltage precharged to the first sensing node SO1 can turn on the separation transistor PM1. Therefore, the voltage of the second sensing node SO2 rises to the second off-cell voltage Vso2_off via the turned-on separation transistor PM1 and the switch transistor PM2.

On the other hand, when sensing the on-cell, the level of the developed first on-cell voltage Vso1_on of the first sensing node SO1 is not high enough to turn on the separation transistor PM1. Therefore, when sensing the on-cell, the separation transistor PM1 is turned off. Even though the switch transistor PM2 is turned on, the voltage of the second sensing node SO2 is maintained at the second on-cell voltage Vso2_on corresponding to the ground GND level by the turn-off of the separation transistor PM1.

At the time point T4, the reset signal RST_S that sets the latch LT according to the development result of the second sensing node SO2 is activated. Then, the trip of the latch node Lat_S occurs. That is, if the sensed memory cell is the on-cell, the latch node Lat_S can be maintained at a high level. On the other hand, if the sensed memory cell is the off-cell, the latch node Lat_S can be inverted to a low level.

Accordingly, the sensing trip control voltage Vdyn, which is the gate voltage of the separation transistor PM1, is fixed to the target level Vtarget. And, the separation transistor PM1 can be turned on or off by the voltage developed at the first sensing node SO1. As a result, the voltage of the first sensing node SO1 can be transferred to the second sensing node SO2 by the level of the voltage developed at the first sensing node SO1 and the switching of the switch transistor PM2. By the sensing method described above, the on-cell margin and the off-cell margin of the memory cell can be provided under the low operating voltage LVDD condition.

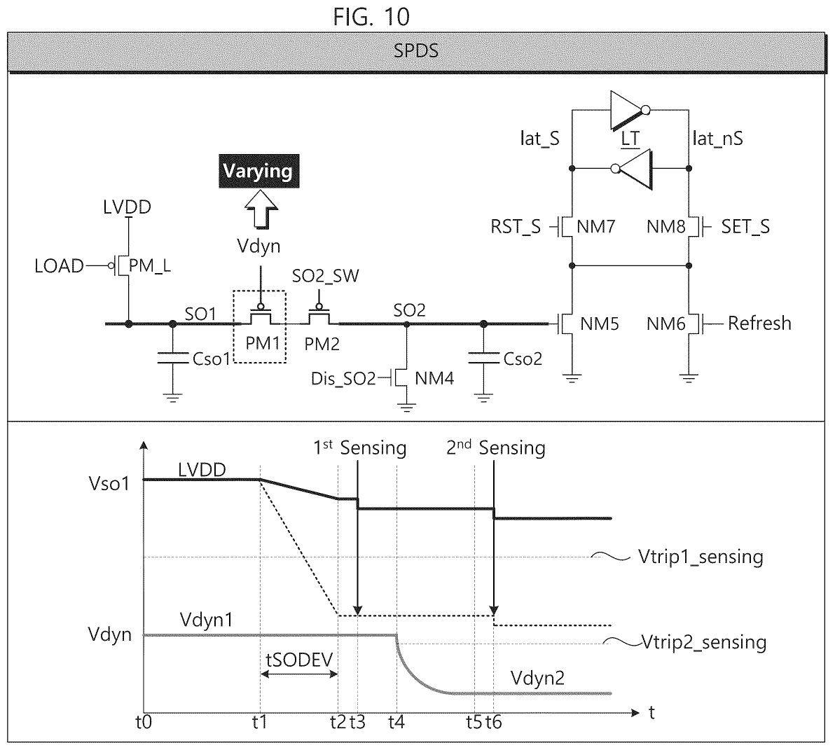

FIG. 10 shows a configuration for applying the Single Precharge Double Sensing (hereinafter, SPDS) technique in the data sensing operation performed in the page buffer of FIG. 5. Referring to FIG. 10, the sensing trip voltage Vtrip_sensing of the page buffer PB0 can be adjusted by varying the sensing trip control voltage Vdyn provided to the gate of the separation transistor PM1.

From time t0 to time t1, a precharge operation for the first sensing node SO1 is performed. At this time, the sensing trip control voltage Vdyn of the separation transistor PM1 is provided as the first sensing trip control voltage Vdyn1. The page buffer PB0 will be set to the first sensing trip voltage Vtrip1_sensing by the first sensing trip control voltage Vdyn1.

From time t1 to time t2, development occurs for the first sensing node SO1, and the separation transistor PM1 is turned on or off according to the voltage of the developed first sensing node SO1. The voltage of the second sensing node SO2 will be set according to the voltage of the developed first sensing node SO1. At time t3, the first sensing for the second sensing node SO2 is performed.

From time t4 to time t5, the sensing trip control voltage Vdyn is adjusted to the second sensing trip control voltage Vdyn2 lower than the first sensing trip control voltage Vdyn1. Then, the channel of the separation transistor PM1 is expanded by the second sensing trip control voltage Vdyn2, and as a result, the page buffer PB0 will be set to the second sensing trip voltage Vtrip2_sensing. Then, at time t3, the second sensing for the second sensing node SO2 can be performed.

Accordingly, sensing can be performed two or more times with one precharge for the first sensing node SO1. This is possible because the sensing trip voltage Vtrip_sensing of the page buffer can be controlled by varying the sensing trip control voltage Vdyn provided to the gate of the separation transistor PM1 multiple times. In addition, by sequentially lowering the gate voltage of the separation transistor PM1, i.e., the sensing trip control voltage Vdyn, the charge of the second sensing node SO2 reduced by the previous sensing can be compensated for.

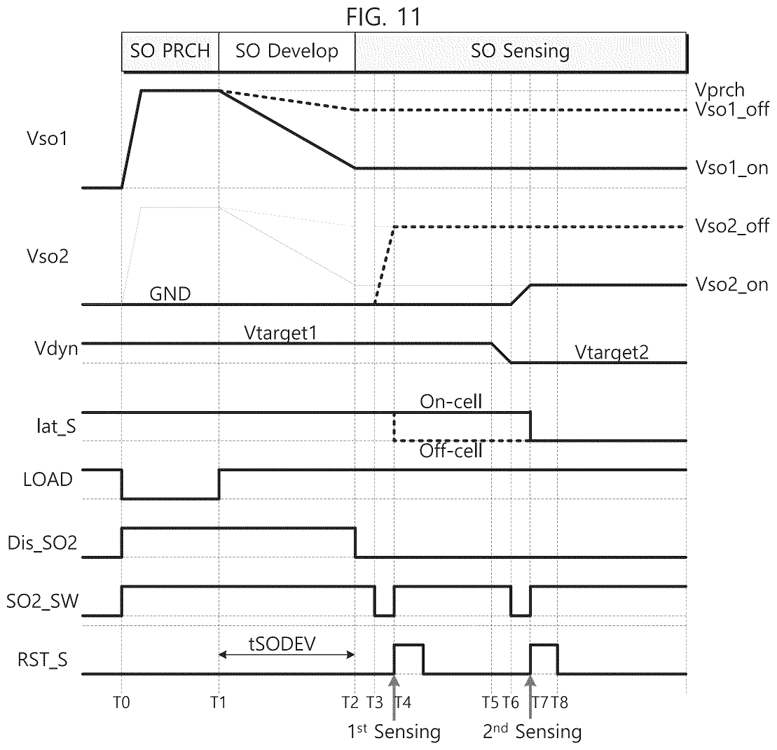

FIG. 11 is a timing diagram showing a data sensing method based on the page buffer structure of FIG. 10. Referring to FIG. 10 and FIG. 11, multiple sensing operations can be performed while adjusting the sensing trip voltage Vtrip_sensing after one precharge using the separated first sensing node SO1 and the second sensing node SO2. The adjustment of the sensing trip voltage Vtrip_sensing can be implemented by adjusting the sensing trip control voltage Vdyn applied to the gate of the separation transistor PM1.

At time T0, the precharge operation of the first sensing node SO1 starts. The load signal LOAD is activated to a low level (or, 0V) for the precharge of the first sensing node SO1. Then, the precharge transistor PM_PCH is turned on, and the first sensing node SO1 will rise to the precharge voltage Vprch level. Then, the discharge control signal Dis_SO2 transitions to a high level to initialize the second sensing node SO2 to the ground GND level. At this time, since the switch control signal SO2_SW is deactivated to a high level, the first sensing node SO1 and the second sensing node SO2 are electrically disconnected regardless of the operation of the separation transistor PM1. In particular, the sensing trip control voltage Vdyn is supplied to the first target voltage Vtarget1 level.

At time T1, the development of the first sensing node SO1 begins. For the development of the first sensing node SO1, the load signal LOAD is deactivated to a high level. When the load signal LOAD is deactivated, the precharge transistor PM_PCH is turned off. Then, the first sensing node SO1 precharged with the precharge voltage Vprch is developed according to the level of the bit line BL. At this time, the discharge control signal Dis_SO2 maintains a high level. And, the switch control signal SO2_SW is deactivated to a high level to electrically disconnect the first sensing node SO1 and the second sensing node SO2. By the development action, the voltage of the first sensing node SO1 precharged with the precharge voltage Vprch level changes to the first off-cell voltage Vso1_off when sensing an off-cell. On the other hand, when sensing an on-cell, the voltage of the first sensing node SO1 precharged to the precharge voltage Vprch level will be lowered to the first on-cell voltage Vso1_on.

At time T2, the initialization of the second sensing node SO2 is completed, and the latch operation of the sensing latch 1325 for the second sensing node SO2 begins. For this, the discharge control signal Dis_SO2 transitions to a low level at time T2. Then, the discharge transistor NM3 is turned off, and the second sensing node SO2 is disconnected from the ground.

From time T3 to time T4, the switch control signal SO2_SW transitions to a low level. Then, the switch transistor PM2 is turned on during the pulse period from time T3 to time T4, and the precharged charge of the first sensing node SO1 moves to the second sensing node SO2. At this time, the sensing trip control voltage Vdyn provided to the gate of the separation transistor PM1 corresponds to the first target voltage Vtarget1. Therefore, the page buffer will operate with the sensing trip voltage Vtrip_sensing of the level corresponding to the first target voltage Vtarget1.

The first sensing starts at time T4. To this end, the reset signal RST_S that sets the latch LT according to the development result of the second sensing node SO2 is activated. Then, the trip of the latch node Lat_S occurs. That is, if the sensed memory cell is an on-cell, the latch node Lat_S can maintain a high level. On the other hand, if the sensed memory cell is an off-cell, the latch node Lat_S can be inverted to a low level.

After the first sensing is completed, the sensing trip control voltage Vdyn provided to the gate of the separation transistor PM1 at time T5 is lowered to the level of the second target voltage Vtarget2. Therefore, the charge consumed in the first sensing section can be replenished to the second sensing node SO2 by the extended channel of the separation transistor PM1. Therefore, the voltage of the second sensing node SO2 can be set to a voltage Vso2_on that is increased from the ground GND level even when it is an on-cell. By adjusting the gate voltage of the separation transistor PM1, the page buffer will operate with the sensing trip voltage Vtrip_sensing of the level corresponding to the second target voltage Vtarget2.

From time T6 to time T7, the switch control signal SO2_SW transitions to a low level. Then, the second sensing starts at time T7. From time T7 to time T8, the reset signal RST_S that sets the latch LT is activated according to the development result of the second sensing node SO2. Then, the trip of the latch node Lat_S occurs, and the data according to the second sensing is latched in the sensing latch 1325. That is, if the sensed memory cell is an on-cell, the latch node Lat_S can maintain a high level. On the other hand, if the sensed memory cell is an off-cell, the latch node Lat_S can be inverted to a low level.

Accordingly, sensing is possible two or more times through one precharge of the first sensing node SO1 by adjusting the sensing trip control voltage Vdyn, which is the gate voltage of the separation transistor PM1.

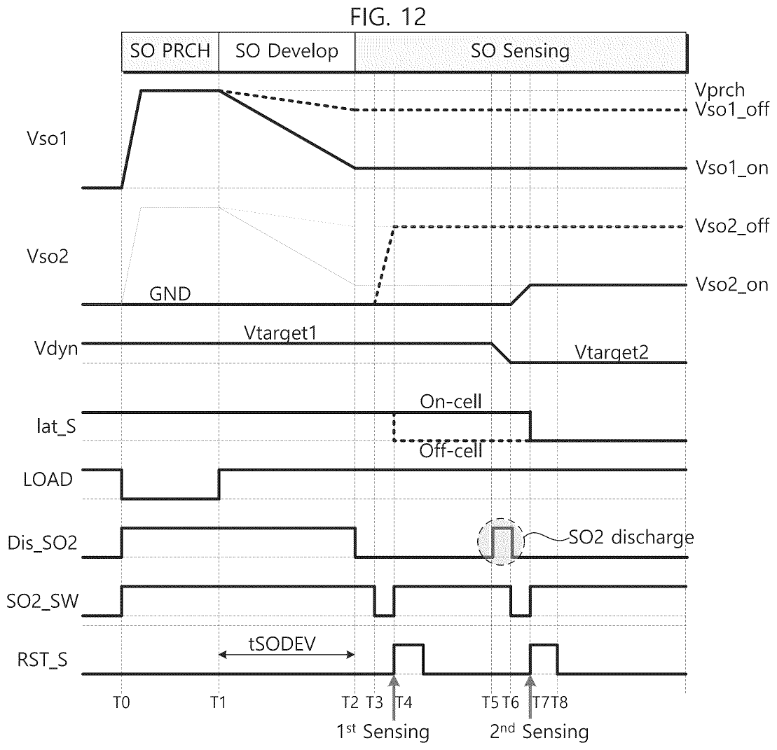

FIG. 12 is a timing diagram showing another example of a data sensing method based on the page buffer structure of FIG. 10. Referring to FIG. 10 and FIG. 12, multiple sensing can be performed while adjusting the sensing trip voltage Vtrip_sensing after one precharge using the separated first sensing node SO1 and second sensing node SO2. The adjustment of the sensing trip voltage Vtrip_sensing can be implemented by adjusting the sensing trip control voltage Vdyn applied to the gate of the separation transistor PM1.

This method is differentiated from that of FIG. 11 in that the number of discharges of the second sensing node SO2 increases. Before the 2nd sensing is performed in the T5 to T6 time interval, the discharge control signal Dis_SO2 is activated to discharge the second sensing node SO2. During the activation period (T5˜T6) of the discharge control signal Dis_SO2, the second sensing node SO2 is connected to the ground GND and all the charged charges can be discharged.

Subsequently, when the switch control signal SO2_SW is activated to a low level at the T6 time interval, the charge precharged to the first sensing node SO1 is transferred to the second sensing node SO2 in an initialized state. Then, the 2nd sensing starts at the T7. That is, the reset signal RST_S that sets the latch LT according to the development result of the second sensing node SO2 is activated. Then, the trip of the latch node Lat_S occurs. In particular, the second sensing node SO2 may be initialized to the ground level just before each sensing point for the second sensing node SO2. Otherwise, the data sensing method of FIG. 12 is substantially the same as the data sensing method of FIG. 11.

Accordingly, sensing is possible two or more times through one sensing node precharge by adjusting the sensing trip control voltage Vdyn, which is the gate voltage of the separation transistor PM1.The second sensing node SO2 is initialized to the ground level for each sensing.

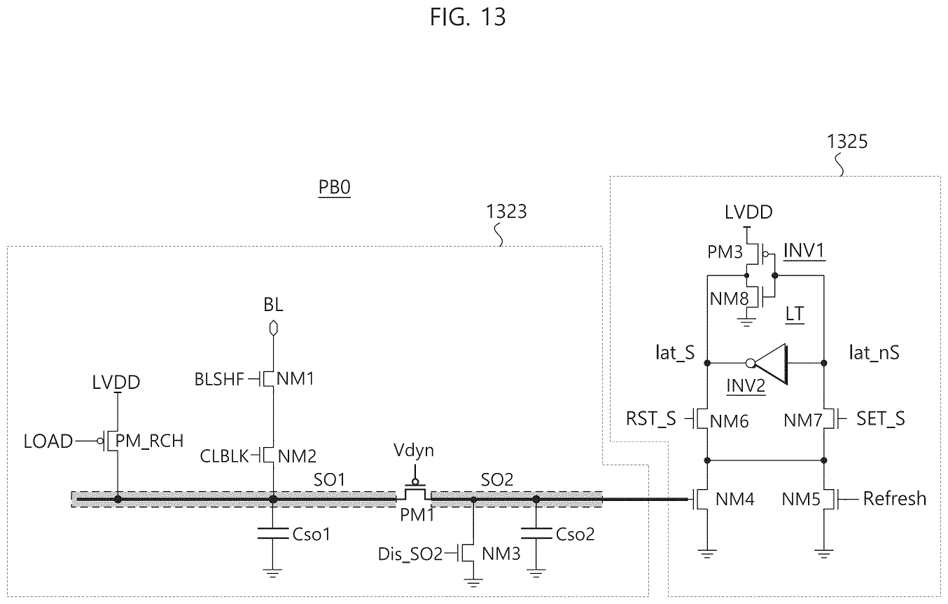

FIG. 13 is a circuit diagram showing another example of the structure of a page buffer having a separated sensing node. Referring to FIG. 13, the page buffer PB0 may include a sensing unit 1323 and a sensing latch 1325. The sensing node of the sensing unit 1323 is separated into a first sensing node SO1 and a second sensing node SO2 by a separation transistor PM1. The sensing unit 1323 has a form in which the switch transistor PM2 for switching the first sensing node SO1 and the second sensing node SO2 is excluded compared to the sensing unit 1321 of FIG. 5.

The sensing unit 1323 may include NMOS transistors NM1 and NM2 for connecting the first sensing node SO1 to the bit line BL. Each of the NMOS transistors NM1 and NM2 is switched by control signals BLSHF and CLBLK. The NMOS transistor NM1 may be driven by a bit line shut-off signal BLSHF, and the NMOS transistor NM2 may be driven by a bit line connection control signal CLBLK. In addition, the sensing unit 1323 may include a precharge transistor PM_PCH formed of a PMOS transistor. The precharge transistor PM_PCH is connected to the first sensing node SO1 and precharges the first sensing node SO1 by a load signal LOAD.

The sensing unit 1323 includes a separation transistor PM1 for dividing the sensing node SO into the first sensing node SO1 and the second sensing node SO2 and driving them individually. The separation transistor PM1 may be formed of a PMOS transistor. A sensing trip control voltage Vdyn provided from a control circuit 1400 is provided to the gate of the separation transistor PM1. During the sensing operation, if the voltage level precharged to the first sensing node SO1 is higher than the sum of the sensing trip control voltage Vdyn and the threshold voltage Vth_dyn of the separation transistor PM1, the separation transistor PM1 is turned on. According to the turn-on of the separation transistor PM1, the charge precharged to the first sensing node SO1 can be shared to the second sensing node SO2.

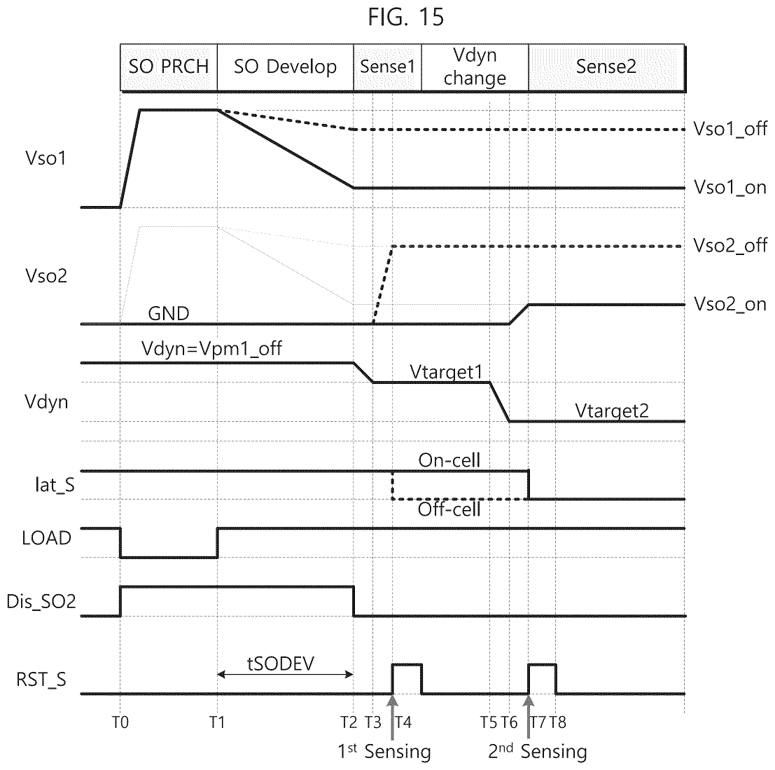

Since the sensing unit 1323 does not include the switch transistor PM2 of FIG. 5, the separation transistor PM1 may be maintained in a turned-off state until the development of the first sensing node SO1 is completed. And, after the development of the first sensing node SO1 is completed, the development voltage of the first sensing node SO1 may transferred to the second sensing node SO2. Therefore, the level of the sensing trip control voltage Vdyn may be lowered to the target voltage Vtarget so that the separation transistor PM1 is turned on when the development of the first sensing node SO1 is completed. The development voltage of the first sensing node SO1 can be transmitted to the second sensing node SO2 by the sensing trip control voltage Vdyn adjusted to the target voltage Vtarget. A detailed description of this data sensing operation will be described in FIG. 15 described below. Ultimately, the role of the switch transistor PM2 can be implemented by adjusting the sensing trip control voltage Vdyn of the separation transistor PM1.

The sensing latch 1325 latches data according to the voltage level of the second sensing node SO2. To this end, the sensing latch 1325 may include an NMOS transistor NM4 of which the gate is connected to the second sensing node SO2, a refresh transistor NM5, a reset transistor NM6, a set transistor NM7, and first and second inverters INV1 and INV2. The first and second inverters INV1 and INV2 may each be composed of a PMOS transistor and an NMOS transistor. For example, the first inverter INV1 includes a PMOS transistor PM3 that operates as a pull-up transistor and an NMOS transistor NM8 that operates as a pull-down transistor. The second inverter INV2 also has the same configuration as the first inverter INV1. An input terminal of the first inverter INV1 and an output terminal of the second inverter INV2 may be connected to an inversion latch node Lat_nS. The output terminal of the first inverter INV1 and the input terminal of the second inverter INV2 can be connected to the latch node Lat_S.

The NMOS transistor NM4 provided for grounding the latch LT is turned on or off according to the voltage level of the second sensing node SO2. The latch LT is tripped at the time when the reset signal RST_S or the set signal SET_S transitions to a high level. That is, the latch LT will be tripped or maintained in the current state depending on the level of the second sensing node SO2. For example, the trip voltage for the level of the second sensing node SO2 of the sensing latch 1325 is determined by the PMOS transistor PM3 and the NMOS transistor NM4 of the first inverter INV1. That is, at the moment of trip, the PMOS transistor PM3 of the first inverter INV1 can operate as a pull-up transistor, and the NMOS transistor NM4 can operate as a pull-down transistor. Under these operating conditions, the trip voltage of the sensing latch 1325 under low operating voltage LVDD conditions can be set through the threshold voltage setting of the pull-up transistors of the inverters INV1 and INV2 and the NMOS transistor NM4.

In the above, a structure of a page buffer PB0 having a separated sensing node that does not include a switch transistor PM2 has been described. The role of the switch transistor PM2 in the structure of FIG. 5 is implemented through the adjustment of the sensing trip control voltage Vdyn of the separation transistor PM1 in FIG. 13.

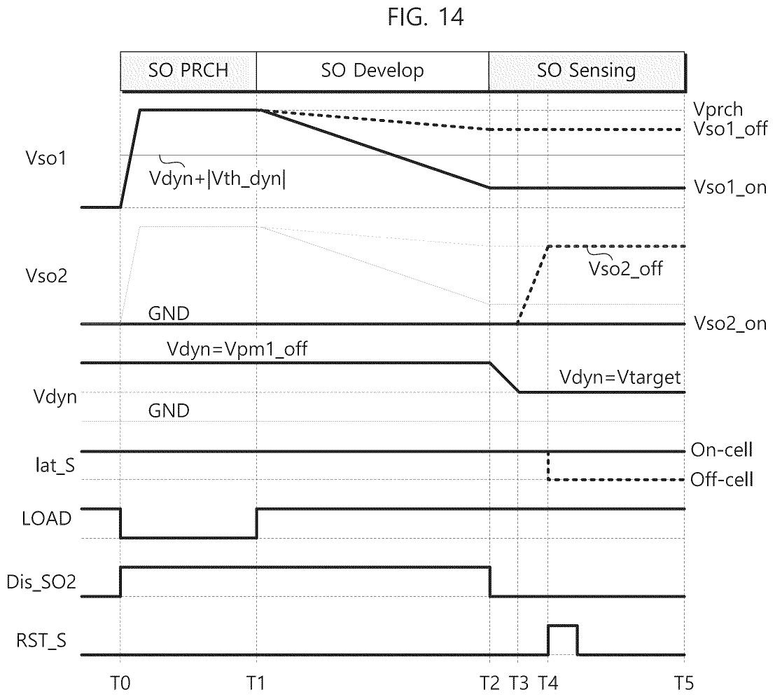

FIG. 14 is a timing diagram showing a data sensing method based on the page buffer of FIG. 13. Referring to FIGS. 13 and 14, whether a memory cell is on-cell or off-cell is detected with a high sensing margin even in a low operating voltage LVDD condition by using a separated first sensing node SO1 and a second sensing node SO2. Here, the sensing trip control voltage Vdyn applied to the gate of the separation transistor PM1 may be provided at a level that turns off the separation transistor PM1 until the development of the first sensing node SO1 is completed. And after the development of the first sensing node SO1 is completed, the sensing trip control voltage

Vdyn may be lowered to the target voltage Vtarget. The target voltage Vtarget can be defined as a turn-on voltage at which the development voltage of the first sensing node SO1 can be transferred to the second sensing node SO2.

At time T0, the precharge operation SO PRCH of the first sensing node SO1 starts. For the precharge of the first sensing node SO1, the load signal LOAD is activated to a low level (or, 0V). Then, the precharge transistor PM_PCH is turned on, and the first sensing node SO1 will rise to the precharge voltage Vprch level. At this time, the discharge control signal Dis_SO2 transitions to a high level to ground the second sensing node SO2. At this time, the sensing trip control voltage Vdyn may be provided at a turn-off level Vpm1_off higher than the target voltage Vtarget to block the separation transistor PM1 until the development of the first sensing node SO1 is completed.

At time T1, the development of the first sensing node SO1 begins. For the development of the first sensing node SO1, the bit line BL and the first sensing node SOL are connected, and the load signal LOAD is deactivated to a high level. The precharge transistor PM_PCH is turned off according to the deactivation of the load signal LOAD. Then, the first sensing node SO1 precharged with the precharge voltage Vprch is developed according to the level of the bit line BL. At this time, the discharge control signal Dis_SO2 maintains a high level. The sensing trip control voltage Vdyn still maintains the turn-off level Vpm1_off.

Due to the development action, the voltage of the first sensing node SO1 precharged to the precharge voltage Vprch level changes to the first off-cell voltage Vso1_off when sensing an off-cell. On the other hand, when sensing an on-cell, the voltage of the first sensing node SO1 precharged to the precharge voltage Vprch level will decrease to the first on-cell voltage Vso1_on.

At time T2, the discharge control signal Dis_SO2 is deactivated to a low level. Then, the discharge transistor NM3 is turned off, and the initialization of the second sensing node SO2 is completed. At the same time, the sensing trip control voltage Vdyn provided to the gate of the separation transistor PM1 is lowered from the turn-off level Vpm1_off to the target voltage Vtarget.

At time T3, the separation transistor PM1 is turned on and the voltage developed at the first sensing node SO1 is transferred to the second sensing node SO2. If an off-cell is sensed, the level of the second sensing node SO2 rises to the second off-cell voltage Vso2_off due to the voltage developed at the first sensing node SO1. On the other hand, if an on-cell is sensed, the level of the second sensing node SO2 will be maintained at a low state or ground GND level due to the voltage developed at the first sensing node SO1.

At the time point T4, the reset signal RST_S that sets the latch LT according to the development result of the second sensing node SO2 is activated. Then, the trip of the latch node Lat_S occurs. That is, if the sensed memory cell is an on-cell, the latch node Lat_S can be maintained at a high level. On the other hand, if the sensed memory cell is an off-cell, the latch node Lat_S can be inverted to a low level.

Accordingly, switching of the first sensing node SO1 and the second sensing node SO2 is possible without the switch transistor PM2 by adjusting the sensing trip control voltage Vdyn provided to the gate of the separation transistor PM1. Therefore, the on-cell margin and the off-cell margin of the memory cell can be provided under the low operating voltage LVDD condition using the circuit structure of FIG. 13.

FIG. 15 is a timing diagram showing another example of a data sensing method based on the page buffer structure of FIG. 13. Referring to FIG. 13 and FIG. 15, multiple sensing operations can be performed while adjusting the sensing trip voltage Vtrip_sensing after one precharge using the separated first sensing node SO1 and second sensing node SO2. The adjustment of the sensing trip voltage Vtrip_sensing can be implemented by adjusting the sensing trip control voltage Vdyn applied to the gate of the separation transistor PM1.

At time T0, the precharge operation of the first sensing node SO1 starts. The load signal LOAD is activated to a low level (or, 0V) for the precharge of the first sensing node SO1. Then, the precharge transistor PM_PCH will be turned on, and the first sensing node SO1 will rise to the precharge voltage Vprch level. At this time, the discharge control signal Dis_SO2 transitions to a high level to ground the second sensing node SO2. At this time, the sensing trip control voltage Vdyn is provided at a turn-off level Vpm1_off higher than the target voltage Vtarget to block the separation transistor PM1 until the development of the first sensing node SO1 is completed.

At time T1, the development of the first sensing node SO1 begins. For the development of the first sensing node SO1, the bit line BL and the first sensing node SOL are connected, and the load signal LOAD is deactivated to a high level. The precharge transistor PM_PCH is turned off by the deactivation of the load signal LOAD. Then, the first sensing node SO1 precharged with the precharge voltage Vprch is developed according to the level of the bit line BL. At this time, the discharge control signal Dis_SO2 maintains a high level. The sensing trip control voltage Vdyn provided to the gate of the separation transistor PM1 still maintains the turn-off level Vpm1_off.

At time T2, the discharge control signal Dis_SO2 is deactivated to a low level. Then, the discharge transistor NM3 is turned off, and the initialization of the second sensing node SO2 is completed. At the same time, the sensing trip control voltage Vdyn provided to the gate of the separation transistor PM1 drops from the turn-off level Vpm1_off to the first target voltage Vtarget1.

At time T3, the separation transistor PM1 is turned on and the voltage developed at the first sensing node SO1 is transferred to the second sensing node SO2. When sensing an off-cell, the level of the second sensing node SO2 rises to the second off-cell voltage Vso2_off due to the voltage developed at the first sensing node SO1. On the other hand, when sensing an on-cell, the level of the second sensing node SO2 will be maintained at a low state or ground GND level due to the voltage developed at the first sensing node SO1.

At time T4, the first sensing for the first sensing node SO1 is started. To this end, the reset signal RST_S that sets the latch LT according to the development result of the second sensing node SO2 is activated. Then, the trip of the latch node Lat_S occurs. That is, if the sensed memory cell is an on-cell, the latch node Lat_S can maintain a high level. On the other hand, if the sensed memory cell is an off-cell, the latch node Lat_S can be inverted to a low level.

At time T5, the sensing trip control voltage Vdyn provided to the gate of the separation transistor PM1 is lowered to the second target voltage Vtarget2 level. Therefore, the charge consumed in the first sensing (1st Sensing) section can be compensated for by the extended channel of the separation transistor PM1 to the second sensing node SO2. Therefore, at time T6, the voltage of the second sensing node SO2 can be set to a voltage Vso2_on that is increased from the ground GND level even if it is an on-cell. The page buffer will operate with a sensing trip voltage Vtrip_sensing corresponding to the second target voltage Vtarget2 by adjusting the gate voltage of the separation transistor PM1.

The second sensing starts from time T7. From time T7 to time T8, the reset signal RST_S that sets the latch LT according to the development result of the second sensing node SO2 is activated. Then, the trip of the latch node Lat_S occurs, and the data according to the second sensing is latched in the sensing latch 1325. That is, if the sensed memory cell is an on-cell, the latch node Lat_S can maintain a high level. On the other hand, if the sensed memory cell is an off-cell, the latch node Lat_S can be inverted to a low level.

Accordingly, sensing is possible two or more times through one precharge of the first sensing node SO1 by adjusting the sensing trip control voltage Vdyn, which is the gate voltage of the separation transistor PM1.

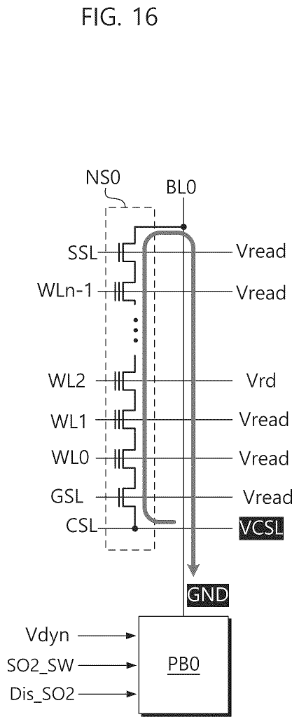

FIG. 16 is a block diagram illustrating an example of a configuration of a cell array and a page buffer circuit. Referring to FIG. 16, each of a plurality of page buffers PB0 to PBk-1 included in a page buffer circuit (e.g., page buffer circuit 1300, see FIG. 4) performs data sensing and latching of a separated sensing node SO in response to a sensing node control signal (Vdyn, SO2_SW, Dis_SO2). For convenience of explanation, the characteristics of a page buffer PB0 connected to a NAND cell string NS0 among a plurality of NAND cell strings will be described as an example.

The NAND cell string NS0 may include a ground selection transistor GST connected to a ground selection line GSL. And the NAND cell string NS0 may include a plurality of memory cells MC0 to MCn-1 each connected to a plurality of word lines WL0 to WLn-1, and a string selection transistor SST connected to a string select line SSL. And the ground selection transistor GST, the plurality of memory cells MC0 to MCn-1, and the string selection transistor SST may be connected in series with each other. In a read operation, a read voltage Vrd is provided to the word line WL2 of the selected memory cell, and a read pass voltage Vread is provided to the word lines WL0˜WL1 and WL3˜WLn-1 of the non-selected memory cells and selection lines SSL and GSL. When the read pass voltage Vread is provided, the memory cell is turned on.

The page buffer PB0 may program or sense data to the selected memory cell. For example, the cell current for identifying whether the selected memory cell is an on-cell or an off-cell during the sensing operation flows from the common source line CSL toward the page buffer PB0. That is, when the selected memory cell to which the read voltage Vrd is provided is an off-cell, the cell current supplied from the common source line CSL is difficult to transfer to the page buffer PB0. On the other hand, when the selected memory cell is an on-cell, the cell current supplied from the common source line CSL is transferred to the page buffer PB0, so that the first sensing node SO1 can be charged to a high level. During the sensing operation, the common source line voltage VCSL supplied to the common source line CSL can be set to an arbitrary level higher than 0V.

The page buffer PB0 has a separated sensing node which can sufficiently provide on-cell margin and off-cell margin even under low operating voltage LVDD conditions and when the cell current flows from the common source line CSL toward the page buffer PB0 during a read operation. By the separated sensing node, the page buffer PB0 can separate the trip voltage Vtrip_sensing of the sensing node SO from the trip voltage Vtrip_latch of the sensing latch. That is, even if it is difficult to lower the voltage of the sensing node SO under low operating voltage LVDD conditions, the trip voltage Vtrip_latch of the sensing latch can be lowered by using the separated sensing node. To this end, the page buffer PB0 can perform data sensing and latching of the separated sensing node SO based on one or more sensing node control signals (Vdyn, SO2_SW, and/or Dis_SO2). In addition, it is possible to adjust the trip voltage Vtrip_latch of the sensing latch to improve cell threshold voltage distribution according to temperature changes. For example, a method of varying the gate voltage Vdyn of the separation transistor according to temperature can be used.

The page buffer PB0 can provide both the on-cell margin and the off-cell margin of the memory cell through the separated sensing node SO structure even when the cell current flows from the common source line CSL to the page buffer PB0 in the low operating voltage LVDD condition and the read operation. Therefore, the non-volatile memory device 1000 can provide high data reliability while satisfying low voltage requirements.

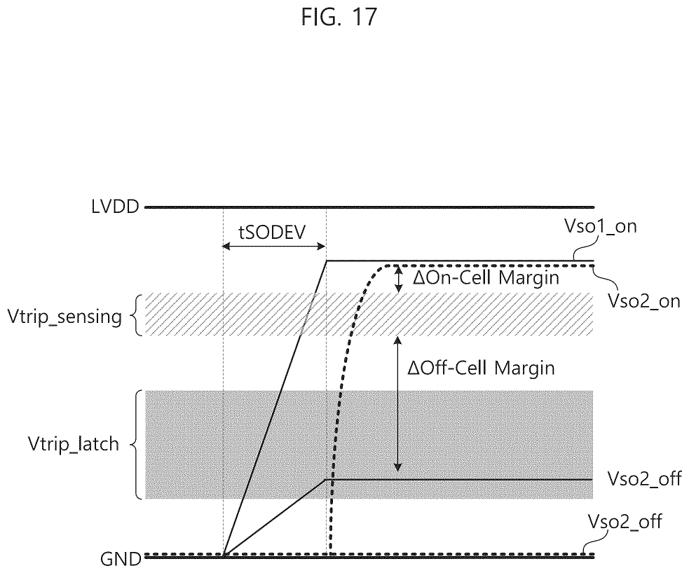

FIG. 17 is a drawing showing operating characteristics of a page buffer according to some implementations of the present disclosure. Referring to FIG. 17, when the cell current flows from the common source line CSL to the page buffer PB0 under the low operating voltage LVDD condition and during the read operation, the sensing trip voltage Vtrip_sensing and the latch trip voltage Vtrip_latch can be separated by separating the sensing node SO.

Assuming that the level of the precharged first sensing node SO1 corresponds to the low operating voltage LVDD, the charge of the precharged first sensing node SO1 is developed according to the cell current of the bit line BL during the sensing node development period tSODEV. In the case of an on-cell, the voltage of the first sensing node SO1 increases as shown in the voltage curve Vso1_on. On the other hand, in the case of an off-cell, the voltage of the first sensing node SO1 is developed as shown in the voltage curve Vso1_off.

When the sensed memory cell corresponds to an on-cell, the level of the first sensing node SO1 becomes higher than the sensing trip voltage Vtrip_sensing set by the gate voltage of the separation transistor PM1. Therefore, the separation transistor PM1 maintains a turn-on state, and the first sensing node SO1 and the second sensing node SO2 are electrically connected. When sensing an on-cell, the level of the second sensing node SO2 rises along with the voltage curve Vso2_on according to the distribution of the charge developed in the first sensing node SO1.

On the other hand, when the sensed memory cell corresponds to an off-cell, the inflow of the cell current into the sensing node is blocked. Therefore, the level of the first sensing node SO1 becomes lower than the sensing trip voltage Vtrip_sensing set by the gate voltage of the separation transistor PM1. Finally, the separation transistor PM1 is turned off, and the first sensing node SO1 and the second sensing node SO2 are electrically disconnected. Therefore, the level of the second sensing node SO2 is maintained at the ground GND level. That is, in the case of an off-cell, the voltage of the second sensing node SO2 corresponds to the voltage curve Vso2_off.

The level of the sensing trip voltage Vtrip_sensing can be controlled by the sensing trip control voltage Vdyn provided to the gate of the separation transistor PM1. And the latch trip voltage Vtrip_latch can be adjusted by setting the threshold voltage of the pull-up transistor of the inverters INV1 and INV2 of the sensing latch (1325, see FIG. 17) and the NMOS transistor NM4. In the case of on-cell, since the voltages of the first sensing node SO1 and the second sensing node SO2 are almost the same, the latch trip voltage Vtrip_latch can be set lower than the sum of the sensing trip control voltage Vdyn and the threshold voltage of the separation transistor PM1.

In addition, in the case of the inverters INV1 and INV2 implemented in the form of a static latch, the variation of the trip voltage was relatively large because it was a P/N fighting structure. For some implementations of the present disclosure, the variation of the trip voltage depends on the threshold voltage variation of the separation transistor PM1 implemented as a PMOS transistor. Therefore, the voltage variation range of the sensing trip voltage Vtrip_sensing can be drastically reduced. Due to these characteristics, the page buffer PB0 can secure sufficient on-cell margin and off-cell margin under low operating voltage LVDD conditions.

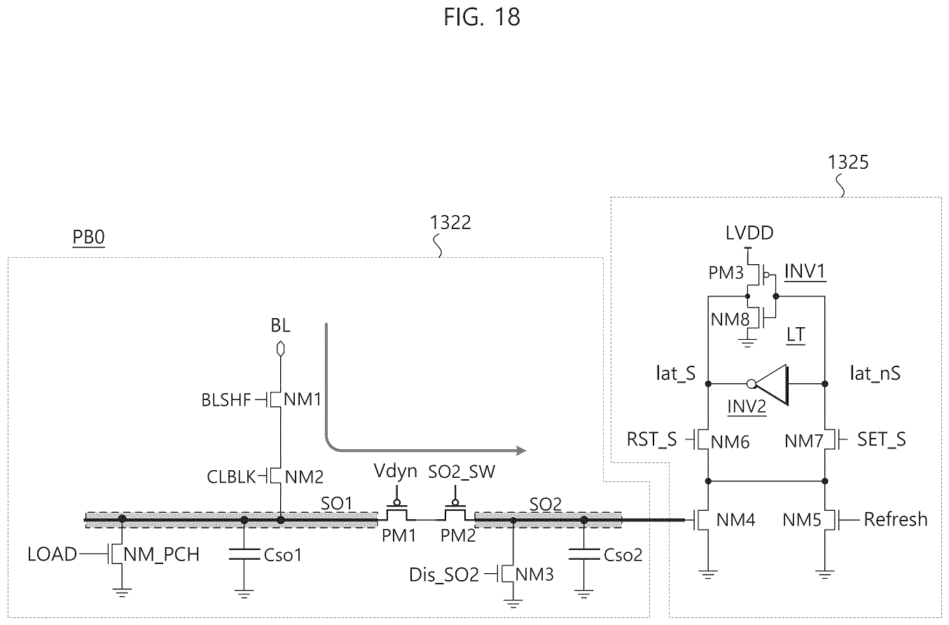

FIG. 18 is a circuit diagram showing an example of a structure of a page buffer having a separated sensing node of FIG. 16. Referring to FIG. 18, the page buffer PB0 may include a sensing unit 1322 and a sensing latch 1325. The sensing node of the sensing unit 1322 is separated into a first sensing node SO1 and a second sensing node SO2 by a separation transistor PM1. In addition, when the bit line is developed, the cell current may flow from the bit line BL to the first sensing node SO1 and the second sensing node SO2.

The sensing unit 1322 may include NMOS transistors NM1 and NM2 for connecting the first sensing node SO1 to the bit line BL. Each of the NMOS transistors NM1 and NM2 is switched by control signals BLSHF and CLBLK. The NMOS transistor NMI can be driven by a bit line shut-off signal BLSHF, and the NMOS transistor NM2 can be driven by a bit line connection control signal CLBLK. In addition, the sensing unit 1322 can further include a precharge transistor NM_PCH connected to the ground and the first sensing node SO1. The precharge transistor NM_PCH can be formed of an NMOS transistor. The precharge transistor NM_PCH can connect the first sensing node SO1 to the ground by a load signal LOAD.

In particular, the sensing unit 1322 includes a separation transistor PM1 for driving the sensing node SO by separating it into the first sensing node SO1 and the second sensing node SO2. The separation transistor PM1 may be formed, for example, as a PMOS transistor. A sensing trip control voltage Vdyn provided from a control circuit 1400 is provided to the gate of the separation transistor PM1. During the sensing operation, if the voltage level precharged to the first sensing node SO1 is higher than the sum of the sensing trip control voltage Vdyn and the threshold voltage Vth_dyn of the separation transistor PM1, the separation transistor PM1 is turned on. According to the turning on of the separation transistor PM1, the charge precharged to the first sensing node SO1 may be shared to the second sensing node SO2.

The switch transistor PM2 may be connected in series between the separation transistor PM1 and the second sensing node SO2. When the separation transistor PM1 is turned on and the charge precharged from the first sensing node SO1 moves to the second sensing node SO2, the amount of charge moved can be controlled according to the pulse width at which the switch transistor PM2 is turned on. The switch transistor PM2 is turned on or off by the switch control signal SO2_SW. Here, the positions of the separation transistor PM1 and the switch transistor PM2 can be exchanged with each other. In addition, a discharge transistor NM3 can be added for initializing the second sensing node SO2. A discharge control signal Dis_SO2 for grounding the second sensing node SO2 is provided to the gate of the discharge transistor NM3.

The sensing latch 1325 latches data according to the voltage level of the second sensing node SO2. To this end, the sensing latch 1325 may include an NMOS transistor NM4 the gates of which are connected to the second sensing node SO2, a refresh transistor NM5, a reset transistor NM6, a set transistor NM7, and first and second inverters INV1 and INV2. The first and second inverters INV1 and INV2 may each be composed of a PMOS transistor and an NMOS transistor. For example, the first inverter INV1 includes a PMOS transistor PM3 that operates as a pull-up transistor and an NMOS transistor NM8 that operates as a pull-down transistor. The second inverter INV2 also has the same configuration as the first inverter INV1. An input terminal of the first inverter INV1 and an output terminal of the second inverter INV2 may be connected to an inversion latch node Lat_nS. The output terminal of the first inverter INV1 and the input terminal of the second inverter INV2 can be connected to the latch node Lat_S.

The NMOS transistor NM4 provided for grounding the latch LT is turned on or off according to the voltage level of the second sensing node SO2. The latch LT is tripped at the time when the reset signal RST_S or the set signal SET_S transitions to a high level. That is, the latch LT will be tripped or maintained in the current state depending on the level of the second sensing node SO2. For example, the trip voltage for the level of the second sensing node SO2 of the sensing latch 1325 is determined by the PMOS transistor PM3 and the NMOS transistor NM8 of the first inverter INV1. That is, at the moment of trip, the PMOS transistor PM3 of the first inverter INV1 can operate as a pull-up transistor, and the NMOS transistor NM8 can operate as a pull-down transistor. By these operating conditions, the latch trip voltage Vtrip_latch of the sensing latch 1325 can be set under the low operating voltage LVDD condition by setting the threshold voltage of the pull-up transistor of the inverters INV1 and INV2 and the NMOS transistor NM4.

Here, the latch LT composed of the inverters INV1 and INV2 can also be composed of a tri-state latch (Tri-state LT: hereinafter, TLT). The tri-state latch TLT includes PMOS transistors (not shown) for switching the low operating voltage LVDD to block the PMOS transistor (e.g., PM3) of the inverters INV1 and INV2 in the high section of the reset signal RST_S where the latch of the trip level occurs. Therefore, the trip level of the tri-state latch TLT is entirely or substantially dependent on the operation of the NMOS transistors (e.g., NM8) of the inverters INV1 and INV2 in the latch section of the sensing node without any racing.

In the above, an example of a structure of a page buffer PB0 having a separated sensing node in a structure in which the cell current flows from the common source line CSL toward the page buffer PB0 under low operating voltage LVDD conditions and during a read operation has been described. Even in a structure in which the cell current flows from the common source line CSL toward the page buffer PB0, it is possible to secure the on-cell margin and the off-cell margin through the separation of the sensing nodes.

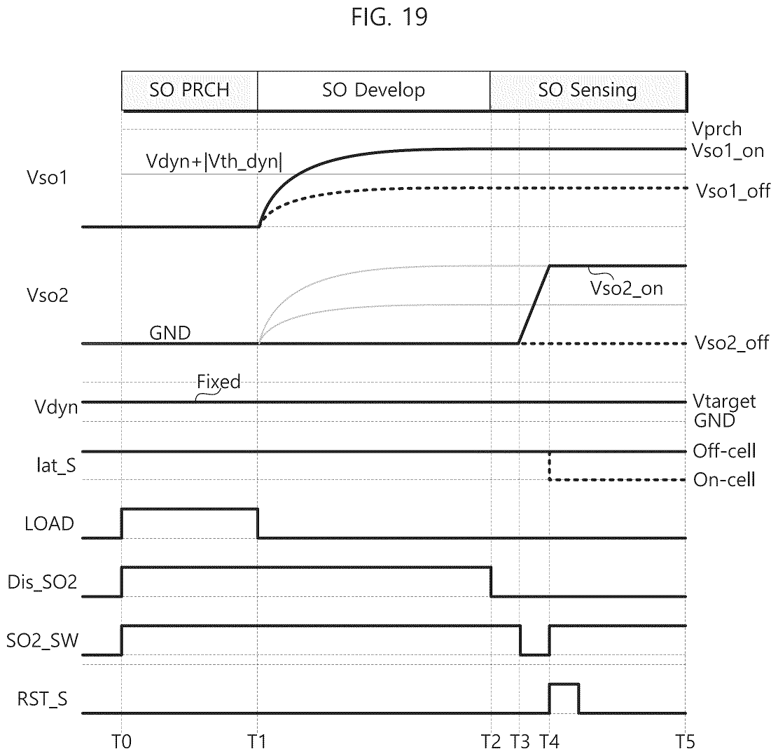

FIG. 19 is a timing diagram showing a control method of a sensing node during a data sensing operation performed in the page buffer of FIG. 18. Referring to FIG. 18 and FIG. 19, whether a memory cell is on-cell or off-cell can be detected with a high sensing margin even in a low operating voltage LVDD environment by using a separated first sensing node SO1 and a second sensing node SO2. Here, the sensing trip control voltage Vdyn applied to the gate of the separation transistor PM1 may be maintained at a fixed level.

At time T0, the precharge operation of the first sensing node SO1 starts. The load signal LOAD transitions to a high level for the precharge of the first sensing node SO1. Then, the precharge transistor NM_PCH is turned on, and the first sensing node SO1 is connected to the ground. Therefore, the first sensing node SO1 can be initialized to the ground level in the precharge period. At this time, the discharge control signal Dis_SO2 transitions to a high level to initialize the second sensing node SO2. And the switch control signal SO2_SW is deactivated to a high level. Then, regardless of the operation of the separation transistor PM1, the first sensing node SO1 and the second sensing node SO2 are electrically disconnected.

At time T1, the development of the first sensing node SO1 is performed. For the development of the first sensing node SO1, the control signal BLSHF connecting the bit line BL and the first sensing node SO1 transitions to a high level. And the load signal LOAD drops to a low level. The precharge transistor NM_PCH is turned off according to the drop of the load signal LOAD. Then, the first sensing node SO1 is developed according to the state of the selected memory cell by the cell current supplied to the bit line BL. At this time, the discharge control signal Dis_SO2 maintains a high level. And, as the switch control signal SO2_SW is deactivated to a high level, the switch transistor PM2 electrically disconnects the first sensing node SO1 and the second sensing node SO2.

Due to the development action, the voltage of the first sensing node SO1 increases relatively significantly, such as the first on-cell voltage Vso1_on indicated by a solid line, when sensing an on-cell. On the other hand, the voltage of the first sensing node SO1 increases slightly, such as the first off-cell voltage Vso1_off indicated by a dotted line, when sensing an off-cell.

At time T2, the latch operation of the sensing latch 1325 for the second sensing node SO2 starts. For this purpose, the discharge control signal Dis_SO2 is deactivated to a low level at time T2. Then, the discharge transistor NM3 is turned off, and the initialization of the second sensing node SO2 is terminated.

From time T3 to time T4, the switch control signal SO2_SW transitions to a low level. Then, the switch transistor PM2 is turned on during the pulse period from time T3 to time T4. At this time, the separation transistor PM1 is turned on or off according to the voltage level of the first sensing node SO1. That is, when the voltage (Vso1) of the first sensing node SO1 is higher than the sum of the sensing trip control voltage Vdyn and the threshold voltage Vth_dyn of the separation transistor PM1, the separation transistor PM1 is turned on. On the other hand, if the voltage Vso1 of the first sensing node SO1 is lower than the sum of the sensing trip control voltage Vdyn and the threshold voltage Vth_dyn of the separation transistor PM1, the separation transistor PM1 is turned off.

At time T3, when sensing an on-cell, the first on-cell voltage Vso1_on precharged to the first sensing node SO1 can turn on the separation transistor PM1. Therefore, the voltage of the second sensing node SO2 increases to the second on-cell voltage Vso2_on via the turned-on separation transistor PM1 and the switch transistor PM2. On the other hand, when sensing an off-cell, the level of the first off-cell voltage Vso1_off of the first sensing node SO1 is not high enough to turn on the separation transistor PM1. Therefore, when sensing an off-cell, the separation transistor PM1 is turned off. Even though the switch transistor PM2 is turned on, the voltage of the second sensing node SO2 is maintained at the second off-cell voltage Vso2_off corresponding to the ground GND level by the turn-off of the separation transistor PM1.

At time T4, the reset signal RST_S that sets the latch LT according to the development result of the second sensing node SO2 is activated. Then, the latch node Lat_S trips. That is, if the sensed memory cell is an on-cell, the latch node Lat_S can maintain a high level. On the other hand, if the sensed memory cell is an off-cell, the latch node Lat_S can be inverted to a low level.

Accordingly, the sensing trip control voltage Vdyn, which is the gate voltage of the separation transistor PM1, is fixed to the target level Vtarget. Then, the separation transistor PM1 can be turned on or off by the voltage developed at the first sensing node SO1. As a result, the voltage of the first sensing node SO1 can be transferred to the second sensing node SO2 by the level of the voltage developed at the first sensing node SO1 and the switching of the switch transistor PM2. By the sensing method described above, the on-cell margin and the off-cell margin of the memory cell can be provided under the low operating voltage LVDD condition where the cell current flows from the common source line CSL toward the page buffer PB0.

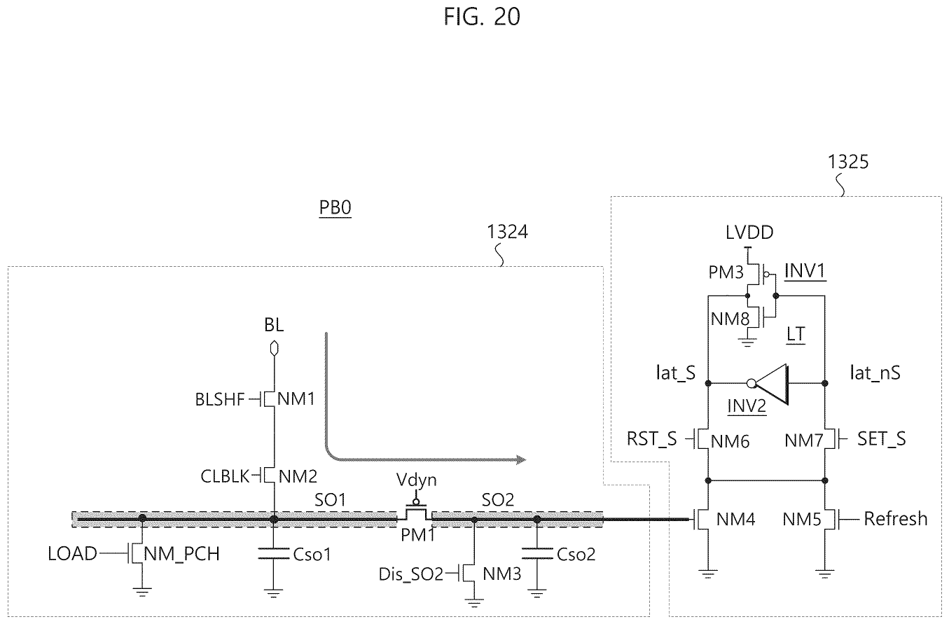

FIG. 20 is a circuit diagram showing another example of a structure of a page buffer having a separated sensing node. Referring to FIG. 20, a page buffer PB0 may include a sensing unit 1324 and a sensing latch 1325. A sensing node of the sensing unit 1324 is separated into a first sensing node SO1 and a second sensing node SO2 by a separation transistor PM1. Compared to the sensing unit 1322 of FIG. 18, the sensing unit 1324 has a form in which a switch transistor PM2 for switching the first sensing node SO1 and the second sensing node SO2 is excluded. Through the page buffer PB0 of the above-described structure, the sensing trip voltage Vtrip_sensing and the latch trip voltage Vtrip_latch can be separated even when the cell current flows from the common source line CSL to the page buffer PB0 in the low operating voltage LVDD condition and the read operation.

The sensing unit 1324 can include NMOS transistors NM1 and NM2 for connecting the first sensing node SO1 to the bit line BL. Each of the NMOS transistors NM1 and NM2 is switched by the control signals BLSHF and CLBLK. The NMOS transistor NM1 can be driven by the bit line shut-off signal BLSHF, and the NMOS transistor NM2 can be driven by the bit line connection control signal CLBLK. In addition, the sensing unit 1324 may further include a precharge transistor NM_PCH connected to the ground and the first sensing node SO1. The precharge transistor NM_PCH may be formed as an NMOS transistor. The precharge transistor NM_PCH may connect the first sensing node SO1 to the ground by a load signal LOAD.

The sensing unit 1324 includes a separation transistor PM1 for dividing the sensing node SO into the first sensing node SO1 and the second sensing node SO2 and driving them individually. The separation transistor PM1 may be formed as a PMOS transistor. A sensing trip control voltage Vdyn provided from a control circuit (1400, see FIG. 2) is provided to the gate of the separation transistor PM1. During the sensing operation, if the voltage level precharged to the first sensing node SO1 is higher than the sum of the sensing trip control voltage Vdyn and the threshold voltage Vth_dyn of the separation transistor PM1, the separation transistor PM1 is turned on. According to the turn-on of the separation transistor PM1, the charge precharged to the first sensing node SO1 can be shared to the second sensing node SO2.

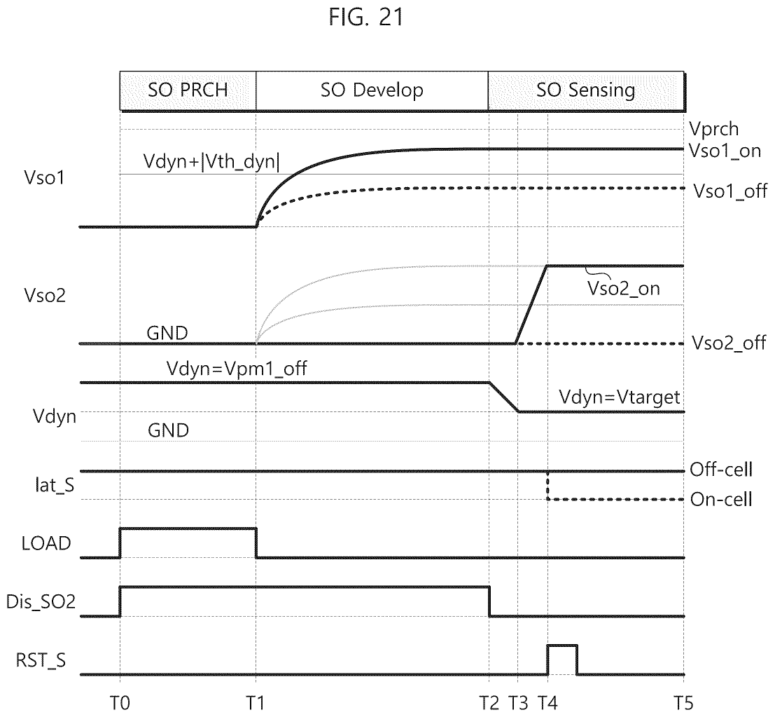

Since the sensing unit 1324 does not include the switch transistor PM2 of FIG. 18, the separation transistor PM1 may be maintained in a turned-off state until the development of the first sensing node SO1 is completed. And after the development of the first sensing node SO1 is completed, the development voltage of the first sensing node SO1 may be transferred to the second sensing node SO2. Therefore, the level of the sensing trip control voltage Vdyn may be lowered to the target voltage Vtarget so that the separation transistor PM1 is turned on when the development of the first sensing node SO1 is completed. The development voltage of the first sensing node SO1 can be transmitted to the second sensing node SO2 by the sensing trip control voltage Vdyn adjusted to the target voltage Vtarget. A detailed description of this data sensing operation will be described later in FIG. 21. Ultimately, the role of the switch transistor PM2 can be implemented by adjusting the sensing trip control voltage Vdyn of the separation transistor PM1.

The sensing latch 1325 latches data according to the voltage level of the second sensing node SO2. To this end, the sensing latch 1325 may include an NMOS transistor NM4 the gate of which are connected to the second sensing node SO2, a refresh transistor NM5, a reset transistor NM6, a set transistor NM7, and first and second inverters INV1 and INV2. The first and second inverters INV1 and INV2 may each be composed of a PMOS transistor and an NMOS transistor. For example, the first inverter INV1 includes a PMOS transistor PM3 that operates as a pull-up transistor and an NMOS transistor NM8 that operates as a pull-down transistor. The second inverter INV2 also has the same configuration as the first inverter INV1. An input terminal of the first inverter INV1 and an output terminal of the second inverter INV2 may be connected to an inversion latch node Lat_nS. The output terminal of the first inverter INV1 and the input terminal of the second inverter INV2 can be connected to the latch node Lat_S.

The NMOS transistor NM4 provided for grounding the latch LT is turned on or off according to the voltage level of the second sensing node SO2. The latch LT is tripped at the time when the reset signal RST_S or the set signal SET_S transitions to a high level. That is, the latch LT will be tripped or maintained in the current state depending on the level of the second sensing node SO2. For example, the trip voltage for the level of the second sensing node SO2 of the sensing latch 1325 is determined by the PMOS transistor PM3 and the NMOS transistor NM8 of the first inverter INV1. That is, at the moment of trip, the PMOS transistor PM3 of the first inverter INV1 can operate as a pull-up transistor, and the NMOS transistor NM8 can operate as a pull-down transistor. By these operating conditions, the trip voltage of the sensing latch 1325 under the low operating voltage LVDD condition can be set through the threshold voltage setting of the pull-up transistor and the NMOS transistor NM4 of the inverters INV1 and INV2.

Here, the latch LT composed of the inverters INV1 and INV2 may be composed of a tri-state latch (Tri-state LT: hereinafter, TLT). The tri-state latch TLT includes PMOS transistors (not shown) for switching the low operating voltage LVDD to block the PMOS transistor (e.g., PM3) of the inverters INV1 and INV2 in the high section of the reset signal RST_S where the latch of the trip level occurs. Therefore, the trip level of the tri-state latch TLT is entirely or substantially dependent on the operation of the NMOS transistors (e.g., NM8) of the inverters INV1 and INV2 in the latch section of the sensing node without any racing.

In the above, an example of a structure of a page buffer PB0 having a separated sensing node that does not include a switch transistor PM2 has been briefly described. The role of the switch transistor PM2 illustrated in the example of FIG. 18 is implemented in FIG. 20 by adjusting the sensing trip control voltage Vdyn of the separation transistor PM1.

FIG. 21 is a timing diagram showing a data sensing method performed in the page buffer of FIG. 20. Referring to FIGS. 20 and 21, a memory cell can be sensed with a high sensing margin even in an environment where a low operating voltage LVDD environment and a cell current flows from a common source line CSL to a page buffer PB0 during a read operation by using a separated first sensing node SO1 and a second sensing node SO2. Here, the sensing trip control voltage Vdyn applied to the gate of the separation transistor PM1 may be provided at the turn-off level of the separation transistor PM1 until the development of the first sensing node SO1 is completed. And, after the development of the first sensing node SO1 is completed, the sensing trip control voltage Vdyn may be lowered to a target level Vtarget. The target level Vtarget can be defined as a turn-on voltage at which the development voltage (e.g., Vso1_on) of the first sensing node SO1 can be transferred to the second sensing node SO2.

At time T0, the precharge operation of the first sensing node SO1 starts. The load signal LOAD transitions to a high level for the precharge of the first sensing node SO1. Then, the precharge transistor NM_PCH is turned on, and the first sensing node SO1 is connected to the ground. Therefore, the first sensing node SO1 can be initialized to the ground level in the precharge period. At this time, the discharge control signal Dis_SO2 transitions to a high level to ground the second sensing node SO2. And the sensing trip control voltage Vdyn may be provided at a turn-off level Vpm1_off higher than the target voltage Vtarget to block the separation transistor PM1 until the development of the first sensing node SO1 is completed.

At time T1, the development of the first sensing node SO1 is performed. For the development of the first sensing node SO1, the control signal BLSHF connecting the bit line BL and the first sensing node SO1 transitions to a high level. And the load signal LOAD drops to a low level. The precharge transistor NM_PCH is turned off according to the drop of the load signal LOAD. Then, the first sensing node SO1 is developed according to the state of the selected memory cell by the cell current supplied to the bit line BL. At this time, the discharge control signal Dis_SO2 maintains a high level. The sensing trip control voltage Vdyn still maintains a turn-off level Vpm1_off.

The voltage of the first sensing node SO1 is developed to a relatively low first off-cell voltage Vso1_off due to a lack of cell current when sensing an off-cell. On the other hand, when sensing an on-cell, the voltage of the first sensing node SO1 will rise to a relatively high first on-cell voltage Vso1_on due to the supply of cell current.

At time T2, the discharge control signal Dis_SO2 is deactivated to a low level. Then, the discharge transistor NM3 is turned off, and the initialization of the second sensing node

SO2 is completed. At the same time, the sensing trip control voltage Vdyn provided to the gate of the separation transistor PM1 is lowered from the turn-off level Vpm1_off to the target voltage Vtarget.

At time T3, the separation transistor PM1 is turned on and the voltage developed at the first sensing node SO1 is transferred to the second sensing node SO2. If the on-cell is sensed, the level of the second sensing node SO2 increases to the second on-cell voltage Vso2_on by the voltage developed at the first sensing node SO1. On the other hand, if the off-cell is sensed, the second sensing node SO2 will maintain the ground GND level by the voltage developed at the first sensing node SO1.

At the time point T4, the reset signal RST_S that sets the latch LT according to the development result of the second sensing node SO2 is activated. Then, the trip of the latch node Lat_S occurs. That is, if the sensed memory cell is an on-cell, the latch node Lat_S can be inverted to a low level. On the other hand, if the sensed memory cell is an off-cell, the latch node Lat_S can be maintained at a high level.

Accordingly, switching of the first sensing node SO1 and the second sensing node SO2 is possible without the switch transistor PM2 by adjusting the sensing trip control voltage Vdyn provided to the gate of the separation transistor PM1. Therefore, the on-cell margin and the off-cell margin of the memory cell can be provided under the low operating voltage LVDD condition using the circuit structure of FIG. 20.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure describes some operations as being performed simultaneously (e.g., changes in voltage applied to transistors), in some implementations the operations can be performed sequentially, without departing from the scope of this disclosure.

While the present disclosure has been described with reference to various examples, it will be apparent to those of ordinary skill in the art that various changes and modifications may be made thereto without departing from the spirit and scope of the present disclosure as set forth in the following claims.

What is claimed is:

1. A non-volatile memory device comprising:
a cell array including memory cells connected to a bit line;
a page buffer configured to sense a state of a memory cell connected to the page buffer via the bit line; and
a control circuit configured to control a sensing operation of the page buffer,
wherein the page buffer comprises:
a first sensing node and a second sensing node;
a separation transistor configured to selectively separate and connect the first sensing node from the second sensing node, and to selectively transmit a voltage developed at the first sensing node to the second sensing node; and
a sensing latch configured to latch data based on a voltage level of the second sensing node.

2. The device of claim 1, wherein the control circuit is configured to provide a sensing trip control voltage to a gate of the separation transistor, and wherein, based on the sensing trip control voltage, the separation transistor is configured to selectively turn on based on the voltage developed at the first sensing node.

3. The device of claim 2, wherein the control circuit is configured to provide the sensing trip control voltage such that a trip voltage of the sensing latch is lower than a sensing trip voltage that is based on the sensing trip control voltage.

4. The device of claim 2, wherein the control circuit is configured to provide the sensing trip control voltage to turn the separation transistor off during a precharge period or a development period of the first sensing node.

5. The device of claim 4, wherein the separation transistor comprises a PMOS transistor, and wherein the control circuit is configured to turn the separation transistor on when the development period ends.

6. The device of claim 1, further comprising:
a discharge transistor configured to couple the second sensing node to ground during a precharge period or a development period of the first sensing node.

7. The device of claim 1, further comprising:
a switch transistor connected in series with the separation transistor and configured to transmit the voltage developed at the first sensing node to the second sensing node.

8. The device of claim 1, wherein the sensing latch comprises a tri-state latch.

9. The device of claim 1, wherein the page buffer is configured to sense the state of the memory cell based on a cell current during a read operation, based on a cell current that flows from the bit line to the first sensing node.

10. The device of claim 9, wherein the control circuit is configured to provide a sensing trip control voltage to a gate of the separation transistor, and
wherein, based on the sensing trip control voltage, the separation transistor is configured to be turned on by a voltage charged to the first sensing node when the memory cell is an on-cell.

11. A data sensing method of a non-volatile memory device, the method comprising:
precharging a first sensing node of a page buffer to provide a precharged first sensing node;
developing the precharged first sensing node based on a program state of a selected memory cell to provide a developed first sensing node;
connecting the developed first sensing node to a second sensing node through a separation transistor based on a sensing trip voltage, wherein the sensing trip voltage is based on a gate voltage of the separation transistor; and
latching data of the selected memory cell in a sensing latch based on a voltage at the second sensing node,
wherein the separation transistor is connected between the first sensing node and the second sensing node, and the sensing trip voltage is higher than a latch trip voltage of the sensing latch.

12. The method of claim 11, comprising:
applying the gate voltage at a fixed level, and
when the separation transistor is turned on by a voltage at the first sensing node, turning on a switch transistor connected in series with the separation transistor between the first sensing node and the second sensing node for a pulse period, to connect the first sensing node to the second sensing node.

13. The method of claim 11, comprising controlling the gate voltage of the separation transistor such that the separation transistor is turned off during the precharging and the development of the first sensing node.

14. The method of claim 13, wherein the separation transistor comprises a PMOS transistor, and
wherein the method comprises lowering the gate voltage of the separation transistor to a target level such that the separation transistor is turned on when the development of the first sensing node is completed.

15. The method of claim 14, comprising initializing the second sensing node to a ground level during the precharging or the development of the first sensing node.

16. The method of claim 11, comprising identifying the program state of the selected memory cell based on a cell current that flows from a common source line to the first sensing node.

17. A non-volatile memory device, comprising:
a memory cell connected to a bit line;
a page buffer configured to sense data stored in the memory cell through the bit line; and
a control circuit configured to control a sensing operation of the page buffer,
wherein the page buffer comprises:
a first sensing node connected to the bit line;
a separation transistor having a first end connected to the first sensing node and a gate configured to receive a sensing trip control voltage;
a second sensing node connected to a second end of the separation transistor; and
a sensing latch configured to latch data based on a voltage level of the second sensing node,
wherein a trip voltage of the separation transistor is based on the sensing trip control voltage, and wherein the control circuit is configured to provide the sensing trip control voltage such that a trip voltage of the sensing latch is lower than a trip voltage of the separation transistor.

18. The device of claim 17, wherein the sensing latch comprises a tri-state latch.

19. The device of claim 18, further comprising:
a discharge transistor configured to ground the second sensing node during a precharge period or a development period of the first sensing node.

20. The device of claim 18, further comprising:
a switch transistor connected in series with the separation transistor between the first sensing node and the second sensing node.
